(19) United States
(12) Patent Application Publication
(10) Pub. No.: US 2026/0043906 A1
(43) Pub. Date: Feb. 12, 2026

(54) PHOTODETECTION DEVICE AND PHOTODETECTION SYSTEM

(71) Applicant: SONY SEMICONDUCTOR SOLUTIONS CORPORATION, KANAGAWA (JP)

(72) Inventor: YASUNORI TSUKUDA, KANAGAWA (JP)

(21) Appl. No.: 19/100,558

(22) PCT Filed: Jun. 14, 2023
(86) PCT No.: PCT/JP2023/022035

§ 371 Date: Jan. 31, 2025

(30) Foreign Application Priority Data
Aug. 8, 2022 (JP) 2022-126612

(51) Int. Cl. G01S 7/4863; H03K 19/20

(52) U.S. Cl. CPC G01S 7/4863; H03K 19/20

(57) ABSTRACT

A photodetection device according to one embodiment of the present disclosure includes: a plurality of light-receiving pixels including a plurality of first light-receiving pixels and a plurality of second light-receiving pixels; a first OR circuit that is configured to generate a first detection signal by performing an OR operation of a plurality of pulse signals generated by the plurality of first light-receiving pixels; a first timing code generation circuit that is configured to generate a first timing code on the basis of the first detection signal; a second OR circuit that is configured to generate a second detection signal by performing an OR operation of a plurality of pulse signals generated by the plurality of second light-receiving pixels; a second timing code generation circuit that is configured to generate a second timing code on the basis of the second detection signal; and a first histogram generation circuit that is configured to generate a first composite signal on the basis of the first timing code and the second timing code, and configured to generate a first histogram on the basis of the first composite signal.

### TECHNICAL FIELD

The present disclosure relates to a photodetection device and a photodetection system that each detect light.

### BACKGROUND ART

A ToF (Time OF Flight) method is frequently used to measure a distance to a detection object. In this ToF method, light is emitted, and reflected light reflected by the detection object is detected. Thereafter, in the ToF method, the distance to the detection object is measured by measuring a time difference between a timing when the light is emitted and a timing when the reflected light is detected. For example, PTL 1 discloses a technology in which OR of output signals of sixteen light-receiving pixels is determined, and a light reception timing is detected on the basis of a result of the determination (for example, PTL 1).

### CITATION LIST

### Patent Literature

PTL 1: Japanese Unexamined Patent Application Publication No. 2021-139647

### SUMMARY OF THE INVENTION

In a photodetection device, enhancement of detection accuracy is desired, and it is expected to further improve the detection accuracy.

It is desirable to provide a photodetection device and a photodetection system that each make it possible to enhance detection accuracy.

A first photodetection device according to one embodiment of the present disclosure includes a plurality of light-receiving pixels, a first OR circuit, a first timing code generation circuit, a second OR circuit, a second timing code generation circuit, and a first histogram generation circuit. The plurality of light-receiving pixels is each configured to detect a light pulse and generate a pulse signal including a pulse corresponding to the light pulse. The plurality of light-receiving pixels includes a plurality of first light-receiving pixels and a plurality of second light-receiving pixels. The plurality of first light-receiving pixels is provided at positions not adjacent to each other, and the plurality of second light-receiving pixels is provided at positions not adjacent to each other. The first OR circuit is configured to generate a first detection signal by performing an OR operation of a plurality of the pulse signals generated by the plurality of first light-receiving pixels. The first timing code generation circuit is configured to generate a first timing code corresponding to a timing when the pulse included in the first detection signal occurs. The second OR circuit is configured to generate a second detection signal by performing an OR operation of a plurality of the pulse signals generated by the plurality of second light-receiving pixels. The second timing code generation circuit is configured to generate a second timing code corresponding to a timing when the pulse included in the second detection signal occurs. The first histogram generation circuit is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.

A second photodetection device according to one embodiment of the present disclosure includes a plurality of light-receiving pixels, a first timing code generation circuit, a second timing code generation circuit, and a first histogram generation circuit. The plurality of light-receiving pixels is each configured to detect a light pulse and generate a pulse signal including a pulse corresponding to the light pulse. The plurality of light-receiving pixels includes a plurality of first light-receiving pixels and a plurality of second light-receiving pixels. The first timing code generation circuit is configured to generate a first timing code corresponding to a timing when the pulse included in the pulse signal generated by the first light-receiving pixel occurs. The second timing code generation circuit is configured to generate a second timing code corresponding to a timing when the pulse included in the pulse signal generated by the second light-receiving pixel occurs. The first histogram generation circuit is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.

A photodetection system according to one embodiment of the present disclosure includes a light source, a plurality of light-receiving pixels, a first OR circuit, a first timing code generation circuit, a second OR circuit, a second timing code generation circuit, and a first histogram generation circuit. The light source is configured to emit a first light pulse. The plurality of light-receiving pixels is each configured to detect a second light pulse corresponding to the first light pulse and generate a pulse signal including a pulse corresponding to the second light pulse. The plurality of light-receiving pixels includes a plurality of first light-receiving pixels and a plurality of second light-receiving pixels. The plurality of first light-receiving pixels is provided at positions not adjacent to each other, and the plurality of second light-receiving pixels is provided at positions not adjacent to each other. The first OR circuit is configured to generate a first detection signal by performing an OR operation of a plurality of the pulse signals generated by the plurality of first light-receiving pixels. The first timing code generation circuit is configured to generate a first timing code corresponding to a timing when the pulse included in the first detection signal occurs. The second OR circuit is configured to generate a second detection signal by performing an OR operation of a plurality of the pulse signals generated by the plurality of second light-receiving pixels. The second timing code generation circuit is configured to generate a second timing code corresponding to a timing when the pulse included in the second detection signal occurs. The first histogram generation circuit is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.

In the first photodetection device and the photodetection system according to the embodiments of the present disclosure, the plurality of light-receiving pixels each detects the light pulse and generates the pulse signal including the pulse corresponding to the light pulse. The plurality of light-receiving pixels includes the plurality of first light-receiving pixels and the plurality of second light-receiving pixels. The plurality of first light-receiving pixels is provided at positions not adjacent to each other, and the plurality of second light-receiving pixels is provided at positions not adjacent to each other. The first OR circuit generates the first detection signal by performing the OR operation of the plurality of pulses signals generated by the plurality of first light-receiving pixels. The first timing code generation circuit generates the first timing code corresponding to the timing when the pulse included in the first detection signal occurs. The second OR circuit generates the second detection signal by performing the OR operation of the plurality of pulse signals generated by the plurality of second light-receiving pixels. The second timing code generation circuit generates the second timing code corresponding to the timing when the pulse included in the second detection signal occurs. The first histogram generation circuit generates the first signal including the plurality of bit signals by decoding the first timing code, and generates the second signal including the plurality of bit signals by decoding the second timing code. Thereafter, the first composite signal is generated by synthesizing the first signal and the second signal, and the first histogram is generated on the basis of the first composite signal.

In the second photodetection device according to the embodiment of the present disclosure, the plurality of light-receiving pixels including the first light-receiving pixels and the second light-receiving pixels each detects the light pulse, and generates the pulse signal including the pulse corresponding to the light pulse. The first timing code generation circuit generates the first timing code corresponding to the timing when the pulse included in the pulse signal generated by the first light-receiving pixel occurs. The second timing code generation circuit generates the second timing code corresponding to the timing when the pulse included in the pulse signal generated by the second light-receiving pixel occurs. The first histogram generation circuit generates the first signal including the plurality of bit signals by decoding the first timing code, and generates the second signal including the plurality of bit signals by decoding the second timing code. Thereafter, the first composite signal is generated by synthesizing the first signal and the second signal, and the first histogram is generated on the basis of the first composite signal.

### BRIEF DESCRIPTION OF DRAWINGS

FIG. 1 is a block diagram illustrating a configuration example of a photodetection system according to one embodiment of the present disclosure.

FIG. 2 is an explanatory diagram illustrating a light pattern of light emitted from a light-emitting section illustrated in FIG. 1.

FIG. 3 is a block diagram illustrating a configuration example of a photodetector illustrated in FIG. 1.

FIG. 4 is a circuit diagram illustrating a configuration example of a light-receiving pixel illustrated in FIG. 3.

FIG. 5 is a timing waveform diagram illustrating an operation example of the light-receiving pixel illustrated in FIG. 4.

FIG. 6 is a circuit diagram illustrating another configuration example of the light-receiving pixel illustrated in FIG. 3.

FIG. 7 is an explanatory diagram illustrating a relationship between a size of the light-receiving pixel illustrated in FIG. 3 and a size of a spot light beam.

FIG. 8 is a circuit diagram illustrating a configuration example of a detection signal generator, a TDC section, and a histogram generator illustrated in FIG. 3.

FIG. 9 is an explanatory diagram illustrating coupling between the light-receiving pixels and subsequent-stage circuits in a pixel array illustrated in FIG. 3.

FIG. 10 is a circuit diagram illustrating a configuration example of a wave-shaping circuit illustrated in FIG. 8.

FIG. 11 is a timing waveform diagram illustrating an operation example of the wave-shaping circuit illustrated in FIG. 10.

FIG. 12 is a circuit diagram illustrating another configuration example of the wave-shaping circuit illustrated in FIG. 8.

FIG. 13 is a timing waveform diagram illustrating an operation example of the TDC section illustrated in FIG. 3.

FIG. 14 is a timing waveform diagram illustrating an operation example of the histogram generator illustrated in FIG. 3.

FIG. 15 is an explanatory diagram illustrating an example of a histogram generated by the histogram generator illustrated in FIG. 3.

FIG. 16 is a block diagram illustrating a configuration example of a photodetector according to a comparative example.

FIG. 17 is a circuit diagram illustrating a configuration example of a detection signal generator, a TDC section, and a histogram generator illustrated in FIG. 16.

FIG. 18 is a timing waveform diagram illustrating an operation example of the TDC section illustrated in FIG. 16.

FIG. 19 is an explanatory diagram illustrating an example of a histogram generated by the histogram generator illustrated in FIG. 16.

FIG. 20 is an explanatory diagram illustrating an example of arrangement of light-receiving pixels according to a modification example.

FIG. 21 is a circuit diagram illustrating a configuration example of a detection signal generator, a TDC section, and a histogram generator according to another modification example.

FIG. 22 is an explanatory diagram illustrating coupling between light-receiving pixels and subsequent-stage circuits according to another modification example.

FIG. 23 is an explanatory diagram illustrating coupling between light-receiving pixels and subsequent-stage circuits according to another modification example.

FIG. 24 is a block diagram illustrating a configuration example of a photodetector according to another modification example.

FIG. 25 is a circuit diagram illustrating a configuration example of a TDC section and a histogram generator illustrated in FIG. 24.

FIG. 26 is an explanatory diagram illustrating coupling between light-receiving pixels and subsequent-stage circuits in a pixel array illustrated in FIG. 24.

FIG. 27 is a circuit diagram illustrating a configuration example of a synthetic circuit in a histogram generation circuit illustrated in FIG. 8.

FIG. 28 is a circuit diagram illustrating a configuration example of a synthetic circuit according to another modification example.

FIG. 29 is a timing waveform diagram illustrating an operation example of the synthetic circuit illustrated in FIG. 28.

FIG. 30 is a circuit diagram illustrating a configuration example of a synthetic circuit according to another modification example.

FIG. 31 is a timing waveform diagram illustrating an operation example of the synthetic circuit illustrated in FIG. 30.

FIG. 32 is an explanatory diagram illustrating an example of selection of light-receiving pixels according to another modification example.

FIG. 33 is a circuit diagram illustrating a configuration example of a detection signal generator, a TDC section, and a histogram generator according to another modification example.

FIG. 34 is an explanatory diagram illustrating coupling between light-receiving pixels and subsequent-stage circuits according to another modification example.

FIG. 35 is a circuit diagram illustrating a configuration example of a tristate inverter illustrated in FIG. 34.

FIG. 36 is a truth table circuit diagram illustrating an operation example of the tristate inverter illustrated in FIG. 34.

FIG. 37 is a circuit diagram illustrating another configuration example of the tristate inverter illustrated in FIG. 34.

FIG. 38 is a circuit diagram illustrating another configuration example of the tristate inverter illustrated in FIG. 34.

FIG. 39 is an explanatory diagram illustrating an installation example of the photodetector illustrated in FIG. 3.

FIG. 40 is an explanatory diagram illustrating another installation example of the photodetector illustrated in FIG. 3.

FIG. 41 is a block diagram depicting an example of schematic configuration of a vehicle control system.

FIG. 42 is a diagram of assistance in explaining an example of installation positions of an outside-vehicle information detecting section and an imaging section.

### MODES FOR CARRYING OUT THE INVENTION

In the following, some embodiments of the present disclosure are described in detail with reference to the drawings. It is to be noted that a description is given in the following order.
1. Embodiment
2. Application Example to Mobile Body

### 1. Embodiment

### Configuration Example

FIG. 1 illustrates a configuration example of a photodetection system (a photodetection system 1) according to an embodiment. The photodetection system 1 includes a ToF sensor, and is configured to emit light to a detection object and detect reflected light reflected by the detection object. The photodetection system 1 includes a light-emitting section 11, an optical system 12, a photodetector 20, and a controller 14.

The light-emitting section 11 is configured to emit a light pulse L0 toward the detection object on the basis of an instruction from the controller 14. The light-emitting section 11 emits the light pulse L0 on the basis of an instruction from the controller 14 by performing a light emission operation of alternately repeating emission and non-emission of light. The light-emitting section 11 includes, for example, a light source that emits infrared light. This light source is configured with use of, for example, a laser light source.

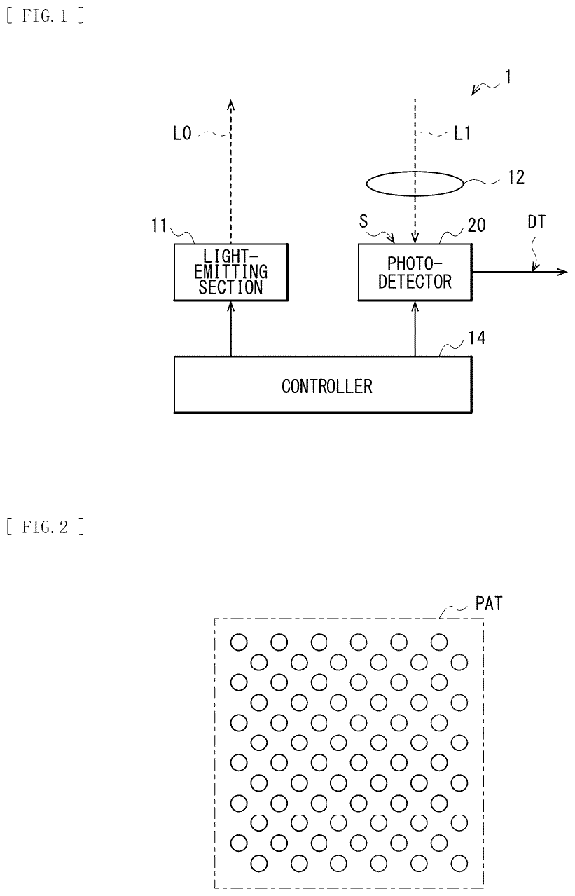

FIG. 2 illustrates a light pattern of the light-emitting section 11. In this example, the light-emitting section 11 includes a plurality of light-emitting elements, and these light-emitting elements each emit a light pulse. Thus, the light-emitting section 11 emits the light pulse L0 with a light pattern including a plurality of spot light beams, as illustrated in FIG. 2.

The optical system 12 (FIG. 1) includes a lens that forms an image on a light-receiving surface S of the photodetector 20. A light pulse (a reflected light pulse L1) emitted from the light-emitting section 11 and reflected by the detection object enters this optical system 12.

The photodetector 20 is configured to detect the reflected light pulse L1 on the basis of an instruction from the controller 14. The photodetector 20 then generates a distance image on the basis of a result of the detection, and outputs image data of the generated distance image as data DT.

The controller 14 is configured to control an operation of the photodetection system 1 by supplying control signals to the light-emitting section 11 and the photodetector 20 and controlling operations of the light-emitting section 11 and the photodetector 20.

With this configuration, the photodetection system 1 repeatedly emits the light pulse L0, and repeatedly detects the reflected light pulse L1 corresponding to this light pulse L0 to thereby generate a histogram of ToF values. The photodetection system 1 then detects a distance to the detection object on the basis of the histogram.

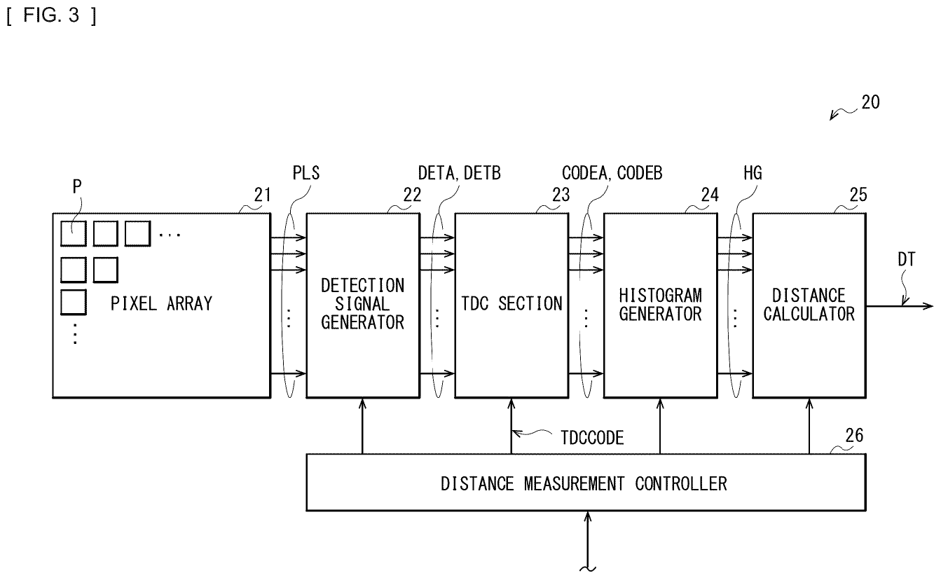

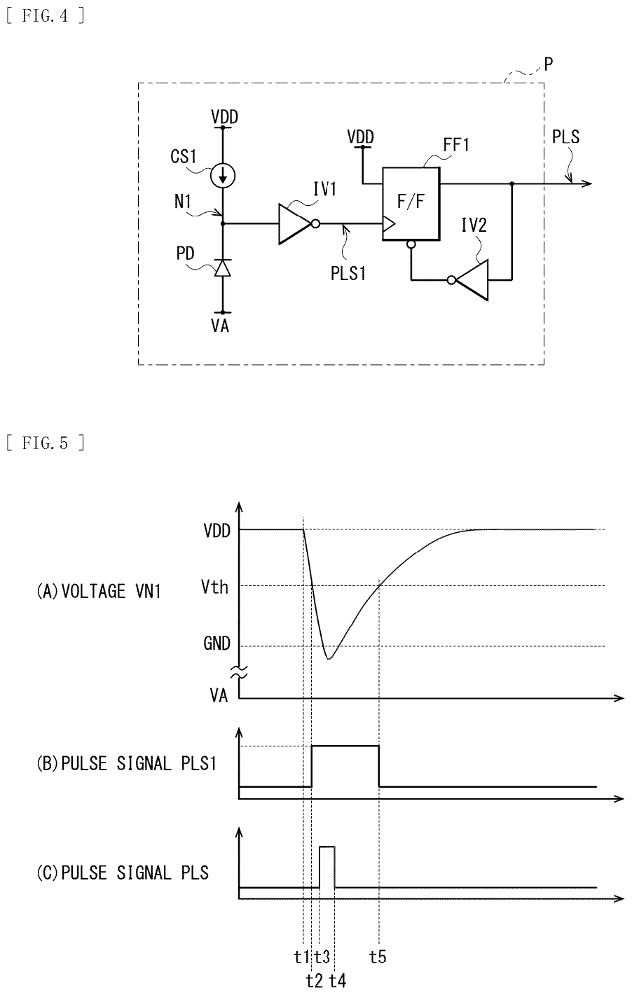

FIG. 3 illustrates a configuration example of the photodetector 20. The photodetector 20 includes a pixel array 21, a detection signal generator 22, a TDC (Time to Digital Converter) section 23, a histogram generator 24, a distance calculator 25, and a distance measurement controller 26.

The pixel array 21 includes a plurality of light-receiving pixels P arranged in a matrix. The plurality of light-receiving pixels P are each configured to generate a pulse signal PLS by detecting the reflected light pulse L1.

FIG. 4 illustrates a configuration example of the light-receiving pixel P. In this example, the light-receiving pixel P includes a photodiode PD, a current source CS1, an inverter IV1, a flip-flop circuit FF1, and an inverter IV2.

The photodiode PD is a photoelectric conversion element that converts light into electric charge. The photodiode PD has an anode to be supplied with a bias voltage VA, and a cathode coupled to a node N1. It is possible to use, for example, a single photon avalanche diode (SPAD; Single Photon Avalanche Diode) for the photodiode PD.

The current source CS1 is configured to cause a predetermined current to flow from a power supply node of a power supply voltage VDD to the node N1.

The inverter IV1 is configured to generate a pulse signal PLS1 by outputting a low level in a case where a voltage at the node N1 is higher than a logic threshold voltage Vth and outputting a high level in a case where the voltage at the node N1 is lower than the logic threshold voltage Vth.

The flip-flop circuit FF1 is a D-type flip-flop circuit, and is configured to have a data input terminal coupled to the power supply node of the power supply voltage VDD, a clock input terminal to be supplied with the pulse signal PLS1, a negative logic reset terminal coupled to an output terminal of the inverter IV2, and an output terminal from which the pulse signal PLS is to be outputted.

The inverter IV2 is configured to generate an inverted signal of the pulse signal PLS and supply the generated signal to the reset terminal of the flip-flop circuit FF1.

FIG. 5 illustrates an operation example of the light-receiving pixel P, where (A) illustrates a waveform of the voltage (a voltage VN1) at the node N1, (B) illustrates a waveform of the pulse signal PLS1, and (C) illustrates a waveform of the pulse signal PLS.

When the reflected light pulse L1 enters the photodiode PD, a current flows from the cathode to the anode of the photodiode PD, and the voltage VN1 at the node N1 starts to decrease from the power supply voltage VDD at a timing t1 ((A) of FIG. 5). Thereafter, when the voltage VN1 falls below the logic threshold voltage Vth at a timing t2, the inverter IV1 changes the pulse signal PLS1 from the low level to the high level ((B) of FIG. 5). The flip-flop circuit FF1 changes the pulse signal PLS from the low level to the high level on the basis of a rising edge of this pulse signal PLS1 at a timing t3 ((C) of FIG. 5). The inverter IV2 changes an output signal from the high level to the low level on the basis of this pulse signal PLS. Accordingly, the flip-flop circuit FF1 is reset at a timing t4, and changes the pulse signal PLS from the high level to the low level.

The voltage VN1 at the node N1 starts to increase after decreasing to some extent, and exceeds the logic threshold voltage Vth at a timing t5 ((A) of FIG. 5). This causes the inverter IV1 to change the pulse signal PLS1 from the high level to the low level ((B) of FIG. 5). Thereafter, the voltage VN1 returns to the power supply voltage VDD. The light-receiving pixel P is not able to receive any light pulse other than this reflected light pulse L1 in a period from the timing t1 to the timing t5 (what is called dead time), but is able to detect the next reflected light pulse L1 at the timing t5 or later.

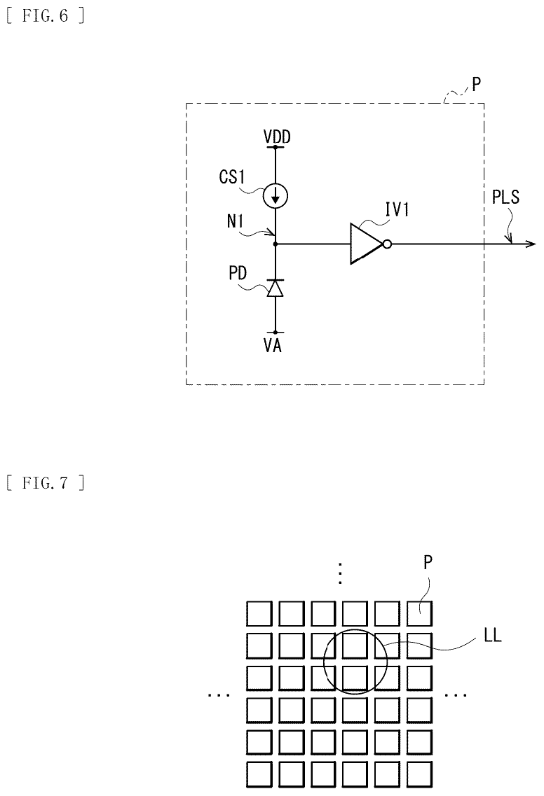

Thus, the light-receiving pixel P illustrated in FIG. 4 is provided with the flip-flop circuit FF1 and the inverter IV2, thus making it possible to narrow a pulse width of the pulse signal PLS, and making it possible to shorten the dead time. It is to be noted that the light-receiving pixel P is not limited to this example, and the flip-flop circuit FF1 and the inverter IV2 may be omitted as illustrated in FIG. 6.

FIG. 7 illustrates a relationship between a size of the light-receiving pixel P and a size of a spot light beam LL of the reflected light pulse L1. The spot light beam LL has a radius substantially equal to the size of the light-receiving pixel P. Accordingly, two light-receiving pixels P adjacent to each other in a longitudinal direction in FIG. 7 are both able to detect one reflected light pulse L1. Likewise, two light-receiving pixels P adjacent to each other in a lateral direction in FIG. 7 are both able to detect one reflected light pulse L1. In contrast, it is difficult for two light-receiving pixels P aligned in an oblique direction in FIG. 7 to both detect one reflected light pulse L1, and one of the two light-receiving pixels P easily detects the one reflected light pulse L1.

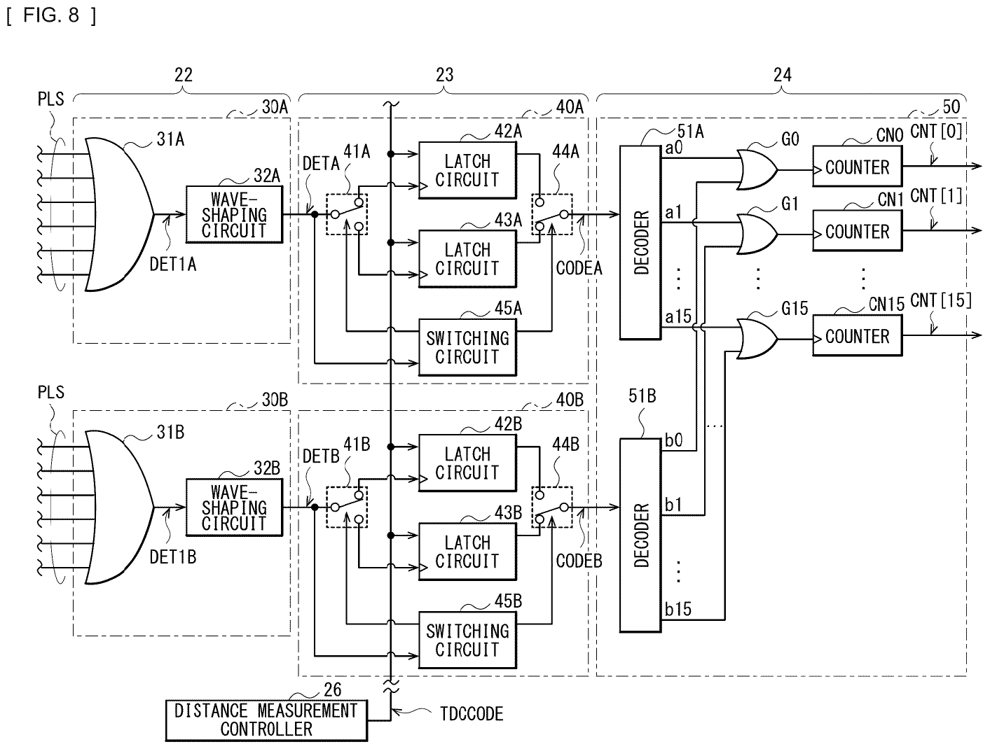

FIG. 8 illustrates a configuration example of the detection signal generator 22, the TDC section 23, and the histogram generator 24. In this example, the photodetection system 1 operates in units of twelve light-receiving pixels P, and generates one histogram HG about detection timings of the reflected light pulse L1 on the basis of results of light reception by the twelve light-receiving pixels P. Circuits illustrated in FIG. 8 are circuits in the detection signal generator 22, the TDC section 23, and the histogram generator 24. The circuits perform operations based on twelve pulse signals PLS supplied from the twelve light-receiving pixels P.

The detection signal generator 22 includes detection signal generation circuits 30A and 30B. The detection signal generation circuits 30A and 30B are configured to generate detection signals DETA and DETB corresponding to the results of light reception by the twelve light-receiving pixels P on the basis of the twelve pulse signals PLS related to the twelve light-receiving pixels P. The detection signal generation circuit 30A includes an OR circuit 31A and a wave-shaping circuit 32A. The detection signal generation circuit 30B includes an OR circuit 31B and a wave-shaping circuit 32B.

The OR circuit 31A is configured to generate a detection signal DET1A by performing an OR operation on the basis of six pulse signals PLS. The OR circuit 31B is configured to generate a detection signal DET1B by performing an OR operation on the basis of six pulse signals PLS.

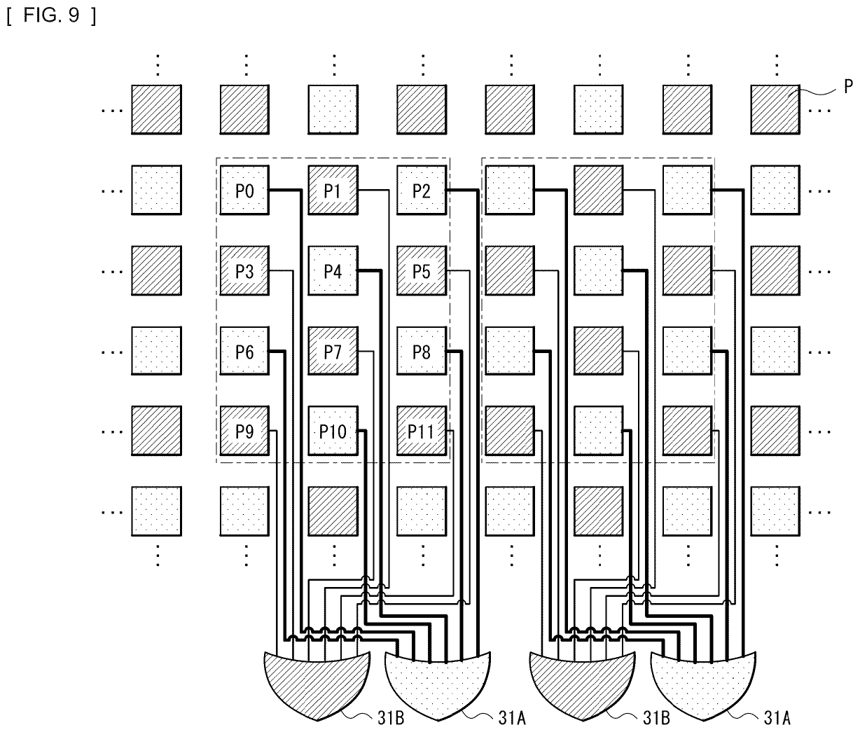

FIG. 9 illustrates an example of coupling between the twelve light-receiving pixels P and the OR circuits 31A and 31B. In this example, the twelve light-receiving pixels P (light-receiving pixels P0 to P11) arranged in a 3×4 pattern are coupled to the OR circuits 31A and 31B. In FIG. 9, the light-receiving pixels P0, P2, P4, P6, P8, and P10 and the OR circuit 31A are indicated by dot-shading, and the light-receiving pixels P1, P3, P5, P7, P9, and P11 and the OR circuit 31B are indicated by diagonal-shading. The dot-shaded light-receiving pixels P0, P2, P4, P6, P8, and P10 are provided at positions not adjacent to each other in the lateral direction and the longitudinal direction. In addition, the diagonal-shaded light-receiving pixels P1, P3, P5, P7, P9, and P11 are provided at positions not adjacent to each other in the lateral direction and the longitudinal direction.

The light-receiving pixels P0, P2, P4, P6, P8, and P10 are coupled to the OR circuit 31A, and the OR circuit 31A performs an OR operation on the basis of six pulse signals PLS supplied from these light-receiving pixels P0, P2, P4, P6, P8, and P10 to thereby generate the detection signal DET1A. In addition, the light-receiving pixels P1, P3, P5, P7, P9, and P11 are coupled to the OR circuit 31B, and the OR circuit 31B performs an OR operation on the basis of six pulse signals PLS supplied from these light-receiving pixels P1, P3, P5, P7, P9, and P11 to thereby generate the detection signal DET1B.

As illustrated in FIG. 7, the two light-receiving pixels P adjacent to each other in the longitudinal direction are both able to detect one reflected light pulse L1. Likewise, the two light-receiving pixels P adjacent to each other in the lateral direction in FIG. 7 are both able to detect one reflected light pulse L1. In contrast, it is difficult for the two light-receiving pixels P aligned in the oblique direction in FIG. 7 to both detect one reflected light pulse L1. Accordingly, for example, it is difficult for two or more of the light-receiving pixels P0, P2, P4, P6, P8, and P10 to detect one reflected light pulse L1. Likewise, for example, it is difficult for two or more of the light-receiving pixels P1, P3, P5, P7, P9, and P11 to detect one reflected light pulse L1. As a result, a plurality of pulses related to one reflected light pulse L1 is difficult to occur in the detection signal DET1A. Likewise, a plurality of pulses related to one reflected light pulse L1 is difficult to occur in the detection signal DET1B.

The wave-shaping circuit 32A (FIG. 8) is configured to generate the detection signal DETA by shaping a waveform of the detection signal DET1A so as to allow the TDC section 23 subsequent to the wave-shaping circuit 32A to stably operate. The wave-shaping circuit 32B is configured to generate the detection signal DETB by shaping a waveform of the detection signal DET1B so as to allow the TDC section 23 subsequent to the wave-shaping circuit 32B to stably operate.

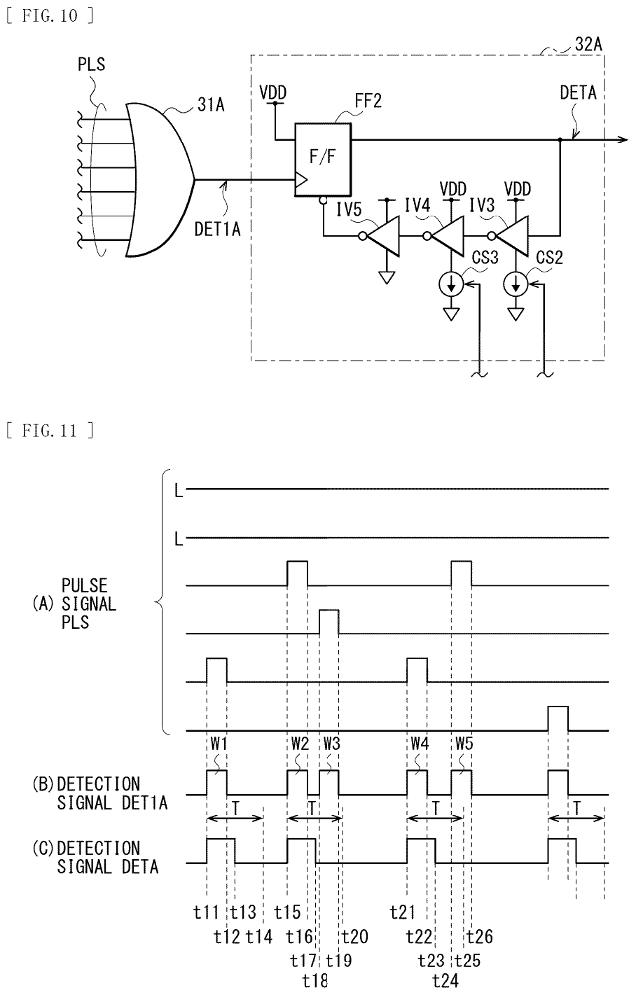

FIG. 10 illustrates a configuration example of the wave-shaping circuit 32A. It is to be noted that FIG. 10 also illustrates the OR circuit 31A. The wave-shaping circuit 32A includes a flip-flop circuit FF2, inverters IV3 to IV5, and current sources CS2 and CS3.

The flip-flop circuit FF2 is a D-type flip-flop circuit, and is configured to have a data input terminal coupled to the power supply node of the power supply voltage VDD, a clock input terminal to be supplied with the detection signal DET1A, a negative logic reset terminal coupled to an output terminal of the inverter IV5, and an output terminal from which the detection signal DETA is to be outputted.

The inverter IV3 is configured to generate an inverted signal of the detection signal DETA. The current source CS2 is provided between a ground terminal of the inverter IV3 and a ground node, and is configured to be able to change a current amount on the basis of a control signal supplied from the distance measurement controller 26. This allows the inverter IV3 to change delay time. Specifically, for example, the inverter IV3 is able to decrease the delay time by increasing the current amount of the current source CS2, and is able to increase the delay time by decreasing the current amount of the current source CS2. The inverter IV4 is configured to generate an inverted signal of the output signal of the inverter IV3. The current source CS3 is provided between a ground terminal of the inverter IV4 and the ground node, and is configured to be able to change a current amount on the basis of a control signal supplied from the distance measurement controller 26. This allows the inverter IV4 to change delay time. The inverter IV5 is configured to generate an inverted signal of the output signal of the inverter IV4 and supply the generated signal to the reset terminal of the flip-flop circuit FF2.

FIG. 11 illustrates an operation example of the detection signal generation circuit 30A including the wave-shaping circuit 32A, where (A) illustrates waveforms of six pulse signals PLS to be inputted to the OR circuit 31A, (B) illustrates a waveform of the detection signal DET1A, and (C) illustrates a waveform of the detection signal DETA.

The OR circuit 31A generates the detection signal DET1A on the basis of the six pulse signals PLS illustrated in (A) of FIG. 11 ((B) of FIG. 11).

The detection signal DET1A includes a pulse W1 that starts at a timing t11 and ends at a timing t12 ((B) of FIG. 11). The flip-flop circuit FF2 changes the detection signal DETA from the low level to the high level on the basis of a rising edge of the detection signal DET1A at the timing t11 ((C) of FIG. 11). This detection signal DETA is inverted and delayed by the inverters IV3 to IV5 and the current sources CS2 and CS3. Thereafter, at a timing t13 when an output signal of the inverter IV5 changes from the high level to the low level, the flip-flop circuit FF2 is reset, and the flip-flop circuit FF2 changes the detection signal DETA from the high level to the low level. This detection signal DETA is inverted and delayed by the inverters IV3 to IV5 and the current sources CS2 and CS3, which causes the output signal of the inverter IV5 to change from the low level to the high level at a timing t14. The flip-flop circuit FF2 is reset in a period from the timing t13 to the timing t14 in such a manner; therefore, the wave-shaping circuit 32A does not receive any pulse other than the pulse W1 in a period T from the timing t11 to the timing t14. Thus, the wave-shaping circuit 32A generates a pulse that starts at the timing t11 and ends at the timing t13. This pulse corresponds to the pulse W1 in the detection signal DET1A.

The detection signal DET1A includes a pulse W2 that starts at a timing t15 and ends at a timing t16, and a pulse W3 that starts at a timing t18 and ends at a timing t19 ((B) of FIG. 11). The flip-flop circuit FF2 changes the detection signal DETA from the low level to the high level on the basis of a rising edge of the detection signal DET1A at the timing t15 ((C) of FIG. 11). This detection signal DETA is inverted and delayed by the inverters IV3 to IV5 and the current sources CS2 and CS3. Thereafter, at a timing t17 when the output signal of the inverter IV5 changes from the high level to the low level, the flip-flop circuit FF2 is reset, and the flip-flop circuit FF2 changes the detection signal DETA from the high level to the low level. This detection signal DETA is inverted and delayed by the inverters IV3 to IV5 and the current sources CS2 and CS3, which causes the output signal of the inverter IV5 to change from the low level to the high level at a timing t20. The flip-flop circuit FF2 is reset in a period from the timing t17 to the timing t20 in such a manner; therefore, the wave-shaping circuit 32A does not receive any pulse other than the pulse W2 in the period T from the timing t15 to the timing t20. Thus, the wave-shaping circuit 32A generates a pulse that starts at the timing t15 and ends at the timing t17. This pulse corresponds to the pulse W2 in the detection signal DET1A.

The detection signal DET1A includes a pulse W4 that starts at a timing t21 and ends at a timing t22, and a pulse W5 that starts at a timing t24 and ends at a timing t26 ((B) of FIG. 11). The flip-flop circuit FF2 changes the detection signal DETA from the low level to the high level on the basis of a rising edge of the detection signal DET1A at the timing t21 ((C) of FIG. 11). This detection signal DETA is inverted and delayed by the inverters IV3 to IV5 and the current sources CS2 and CS3. Thereafter, at a timing t23 when the output signal of the inverter IV5 changes from the high level to the low level, the flip-flop circuit FF2 is reset, and the flip-flop circuit FF2 changes the detection signal DETA from the high level to the low level. This detection signal DETA is inverted and delayed by the inverters IV3 to IV5 and the current sources CS2 and CS3, which causes the output signal of the inverter IV5 to change from the low level to the high level at a timing t25. The flip-flop circuit FF2 is reset in a period from the timing t23 to the timing t25 in such a manner; therefore, the wave-shaping circuit 32A does not receive any pulse other than the pulse W4 in the period T from the timing t21 to the timing t25. Thus, the wave-shaping circuit 32A generates a pulse that starts at the timing t21 and ends at the timing t23. This pulse corresponds to the pulse W4 in the detection signal DET1A.

Thus, the wave-shaping circuit 32A generates a pulse on the basis of a pulse included in the detection signal DET1A and thereafter operates not to generate a pulse for a predetermined time, thereby generating the detection signal DETA.

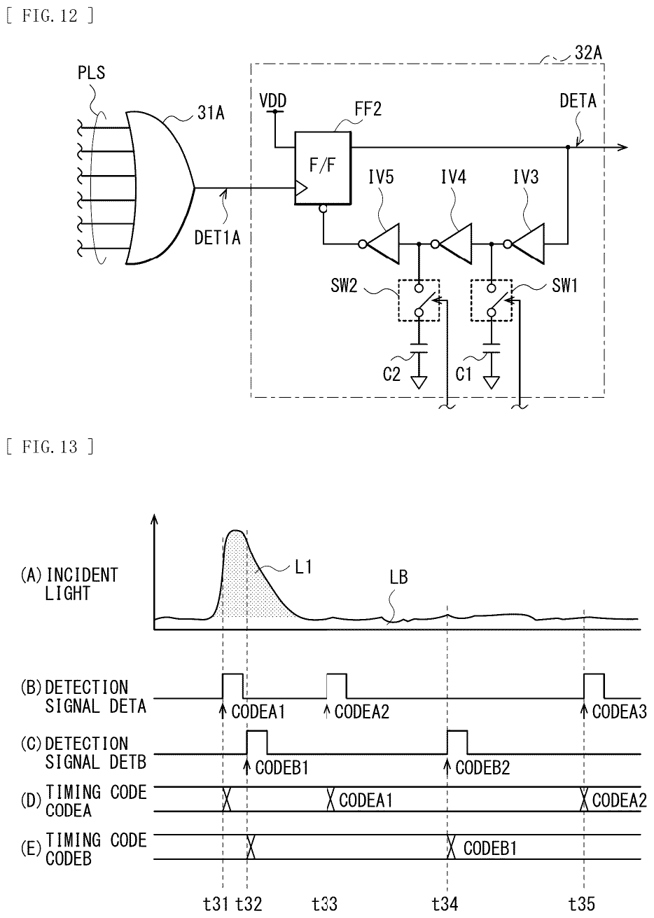

In this example, as illustrated in FIG. 10, the wave-shaping circuit 32A uses the current sources CS2 and CS3 to enable adjustment of delay time, but this is not limitative. Instead of this, for example, as illustrated in FIG. 12, a capacitor element may be used to enable adjustment of delay time. In this example, the wave-shaping circuit 32A includes switches SW1 and SW2 and capacitors C1 and C2. The switch SW1 is configured to turn on or off on the basis of a control signal supplied from the distance measurement controller 26, and has one end coupled to an output terminal of the inverter IV3, and another end coupled to the capacitor C1. The capacitor C1 has one end coupled to the other end of the switch SW1, and another end coupled to the ground node. This allows the inverter IV3 to change the delay time. Specifically, for example, the inverter IV3 is able to decrease the delay time by turning off the switch SW1, and is able to increase the delay time by turning on the switch SW1. The switch SW2 is configured to turn on or off on the basis of a control signal supplied from the distance measurement controller 26, and has one end coupled to an output terminal of the inverter IV4, and another end coupled to the capacitor C2. The capacitor C2 has one end coupled to the other end of the switch SW2, and another end coupled to the ground node. This allows the inverter IV4 to change the delay time.

Although the wave-shaping circuit 32A has been described above as an example, the same applies to the wave-shaping circuit 32B.

The TDC section 23 (FIG. 8) includes TDC circuits 40A and 40B. The TDC circuits 40A and 40B are configured to generate timing codes CODEA and CODEB corresponding to detection timings of the reflected light pulse L1 in the twelve light-receiving pixels P on the basis of the detection signals DETA and DETB related to the twelve light-receiving pixels P. The TDC circuit 40A includes a switch 41A, latch circuits 42A and 43A, a switch 44A, and a switching circuit 45A. The TDC circuit 40B includes a switch 41B, latch circuits 42B and 43B, a switch 44B, and a switching circuit 45B.

The switch 41A is configured to supply the detection signal DETA to the latch circuit 42A or the latch circuit 43A on the basis of a control signal supplied from the switching circuit 45A. Each of the latch circuits 42A and 43A is configured to latch a counter code TDCCODE supplied from the distance measurement controller 26 on the basis of the detection signal DETA supplied from the switch 41A and output the latched code. The counter code TDCCODE is a code of four bits in this example. It is to be noted that the counter code TDCCODE is not limited thereto. Instead of the code of four bits, the counter code TDCCODE may be a code of three or less bits, or may be a code of five or more bits. The switch 44A is configured to select one from a code supplied from the latch circuit 42A and a code supplied from the latch circuit 43A on the basis of a control signal supplied from the switching circuit 45A and output the selected code as a timing code CODEA. The switching circuit 45A is a state machine that controls operations of the switches 41A and 44A on the basis of the detection signal DETA. The switching circuit 45A changes over the switch 41A and changes over the switch 44A every time a pulse occurs in the detection signal DETA. For example, in a case where the switch 41A supplies the detection signal DETA to the latch circuit 42A, the switch 44A outputs the code supplied from the latch circuit 43A as the timing code CODEA. In addition, for example, in a case where the switch 41A supplies the detection signal DETA to the latch circuit 43A, the switch 44A outputs the code supplied from the latch circuit 42A as the timing code CODEA. Thus, the TDC circuit 40A generates the timing code CODEA corresponding to a timing when the pulse included in the detection signal DETA occurs, and outputs this timing code CODEA at a timing when a pulse subsequent to the pulse in the detection signal DETA occurs.

The switch 41B is configured to supply the detection signal DETB to the latch circuit 42B or the latch circuit 43B on the basis of a control signal supplied from the switching circuit 45B. Each of the latch circuits 42B and 43B is configured to latch the counter code TDCCODE supplied from the distance measurement controller 26 on the basis of the detection signal DETB supplied from the switch 41B and output the latched code. The switch 44B is configured to select one from a code supplied from the latch circuit 42B and a code supplied from the latch circuit 43B on the basis of a control signal supplied from the switching circuit 45B and output the selected code as the timing code CODEB. The switching circuit 45A is a state machine that controls operations of the switches 41B and 44B on the basis of the detection signal DETB. Operations of the switch 41B, the latch circuits 42B and 43B, the switch 44B, and the switching circuit 45B are similar to operations of the switch 41A, the latch circuits 42A and 43A, the switch 44A, and the switching circuit 45A.

The histogram generator 24 includes a histogram generation circuit 50. The histogram generation circuit 50 is configured to generate the histogram HG on the basis of the timing codes CODEA and CODEB related to the twelve light-receiving pixels P. The histogram generation circuit 50 includes decoders 51A and 51B, a plurality of OR circuits (sixteen OR circuits G0 to G15 in this example), and a plurality of counters (sixteen counters CN0 to CN15 in this example).

The decoder 51A is configured to generate a plurality of signals (sixteen signals a0 to a15 in this example) by decoding the timing code CODEA of a plurality of bits (four bits in this example). For example, in a case where the timing code CODEA is “0000”, the decoder 51A sets the signal a0 to “1”, and sets the other signals a1 to a15 to “0”. For example, in a case where the timing code CODEA is “0001”, the decoder 51A sets the signal a1 to “1”, and sets the other signals a0 and a2 to a15 to “0”. For example, in a case where the timing code CODE is “1111”, the decoder 51A sets the signal a15 to “1”, and sets the other signals a0 to a14 to “0”.

The decoder 51B is configured to generate a plurality of signals (sixteen signals b0 to b15 in this example) by decoding the timing code CODEB of a plurality of bits (four bits in this example). An operation of the decoder 51B is similar to an operation of the decoder 51A.

The OR circuit G0 is configured to determine OR of the signal a0 supplied from the decoder 51A and the signal b0 supplied from the decoder 51B. The OR circuit G1 is configured to determine OR of the signal a1 supplied from the decoder 51A and the signal b1 supplied from the decoder 51B. The same applies to the OR circuits G2 to G15. Thus, the OR circuits G0 to G15 synthesize the signals a0 to a15 supplied from the decoder 51A and signals b0 to b15 supplied from the decoder 51B.

The counter CN0 is configured to generate a count value CNT[0] by performing a counting operation on the basis of a rising edge of an output signal of the OR circuit G0. The counter CN1 is configured to generate a count value CNT[1] by performing a counting operation on the basis of a rising edge of an output signal of the OR circuit G1. The same applies to the counters CN2 to CN15.

With this configuration, the counters CN0 to CN15 respectively increment count values CNT[0] to CNT[15] on the basis of the timing code CODEA and the timing code CODEB. The count values CNT[0] to CNT[15] generated by the histogram generation circuit 50 configure the histogram HG representing detection timings of the reflected light pulse L1 in the twelve light-receiving pixel P. The photodetection system 1 operates in units of twelve light-receiving pixels P, which causes the histogram generator 24 to generate a plurality of histograms HG. Thereafter, the histogram generator 24 supplies information about the plurality of generated histograms HG to the distance calculator 25.

Circuits illustrated in FIG. 8 are circuits in the detection signal generator 22, the TDC section 23, and the histogram generator 24. The circuits perform operations based on twelve pulse signals PLS supplied from the twelve light-receiving pixels P. Accordingly, the detection signal generator 22 includes a plurality of detection signal generation circuits 30A and a plurality of detection signal generation circuits 30B. The TDC section 23 includes a plurality of TDC circuits 40A and a plurality of TDC circuits 40B. The histogram generator 24 includes a plurality of histogram generation circuits 50.

The distance calculator 25 (FIG. 3) is configured to calculate, on the basis of each of the plurality of histograms HG, a distance value between the photodetection system 1 and a measurement object, on the basis of an instruction from the distance measurement controller 26. In such a manner, the distance calculator 25 generates a distance image, and outputs image data of the generated distance image as the data DT.

The distance measurement controller 26 (FIG. 3) is configured to control operations of the detection signal generator 22, the TDC section 23, the histogram generator 24, and the distance calculator 25 on the basis of an instruction from the controller 14 (FIG. 1).

Here, the light-receiving pixels P0, P2, P4, P6, P8, and P10 correspond to a specific example of a “plurality of first light-receiving pixels” in an embodiment of the present disclosure The light-receiving pixels P1, P3, P5, P7, P9, and P11 correspond to a specific example of a “plurality of second light-receiving pixels” in an embodiment of the present disclosure. The pulse signal PLS corresponds to a specific example of a “pulse signal” in an embodiment of the present disclosure. The OR circuit 31A corresponds to a specific example of a “first OR circuit” in an embodiment of the present disclosure. The detection signal DETA corresponds to a specific example of a “first detection signal” in an embodiment of the present disclosure. The OR circuit 31B corresponds to a specific example of a “second OR circuit” in an embodiment of the present disclosure. The detection signal DETB corresponds to a specific example of a “second detection signal” in an embodiment of the present disclosure. The TDC circuit 40A corresponds to a specific example of a “first timing code generation circuit” in an embodiment of the present disclosure. The timing code CODEA corresponds to a specific example of a “first timing code” in an embodiment of the present disclosure. The TDC circuit 40B corresponds to a specific example of a “second timing code generation circuit” in an embodiment of the present disclosure. The timing code CODEB corresponds to a specific example of a “second timing code” in an embodiment of the present disclosure. The histogram generation circuit 50 corresponds to a specific example of a “first histogram generation circuit” in an embodiment of the present disclosure. The signals a0 to a15 each correspond to a specific example of a “first signal” in an embodiment of the present disclosure. The signals b0 to b15 each correspond to a specific example of a “second signal” in an embodiment of the present disclosure. The histogram HG corresponds to a specific example of a “first histogram” in an embodiment of the present disclosure.

### Operation and Workings

Next, a description is given of an operation and workings of the photodetection system 1 according to the present embodiment.

### Overview of Overall Operation

First, an overview of the overall operation of the photodetection system 1 is described with reference to FIGS. 1 and 3. The light-emitting section 11 emits the light pulse L0 toward the detection object. The optical system 12 forms an image on the light-receiving surface S of the photodetector 20. The photodetector 20 detects the reflected light pulse L1. The controller 14 supplies control signals to the light-emitting section 11 and the photodetector 20 and controls operations of the light-emitting section 11 and the photodetector 20 to thereby control a distance measuring operation of the photodetection system 1.

In the photodetector 20, the light-receiving pixels P of the pixel array 21 each generate the pulse signal PLS by detecting light. The detection signal generation circuits 30A and 30B of the detection signal generator 22 generate detection signals DETA and DETB corresponding to results of light reception by twelve light-receiving pixels P on the basis of twelve pulse signals PLS related to the twelve light-receiving pixels P. The TDC circuits 40A and 40B of the TDC section 23 generate the timing codes CODEA and CODEB corresponding to detection timings of the reflected light pulses L in the twelve light-receiving pixels P on the basis of the detection signals DETA and DETB related to the twelve light-receiving pixels P. The histogram generation circuit 50 of the histogram generator 24 generates the histograms HG on the basis of the timing codes CODEA and CODEB related to the twelve light-receiving pixels P. The distance calculator 25 is configured to calculate the distance value between the photodetection system 1 and the measurement object on the basis of each of the plurality of histograms HG. Thus, the distance calculator 25 generates the distance image and outputs the image data of the generated distance image as the data DT. The distance measurement controller 26 controls the operations of the detection signal generator 22, the TDC section 23, the histogram generator 24, and the distance calculator 25 on the basis of an instruction from the controller 14 on the basis of an instruction from the controller 14.

### Detailed Operation

Next, a detailed description is given of the operation of the photodetection system 1.

FIG. 13 illustrates an operation example of the TDC section 23, where (A) illustrates an optical waveform of incident light on the pixel array 21, (B) illustrates a waveform of the detection signal DETA, (C) illustrates a waveform of the detection signal DETB, (D) illustrates the timing code CODEA, and (E) illustrates the timing code CODEB. In this example, the reflected light pulse L1 enters the pixel array 21 around a timing t31 ((A) of FIG. 13). Light intensity of this reflected light pulse L1 is inversely proportional to the square of the distance to the measurement object. In addition, background light LB also enters the pixel array 21.

The detection signal generation circuit 30A of the detection signal generator 22 outputs a pulse starting from the timing t31 as the detection signal DETA on the basis of six pulse signals PLS supplied from six light-receiving pixels P (the light-receiving pixels P0, P2, P4, P6, P8, and P10) ((B) of FIG. 13). This pulse is a pulse corresponding to the reflected light pulse L1. The TDC circuit 40A of the TDC section 23 latches the counter code TDCCODE on the basis of a rising edge of the pulse of this detection signal DETA to thereby generate a code CODEA1.

Next, the detection signal generation circuit 30B of the detection signal generator 22 outputs a pulse starting from a timing t32 as the detection signal DETB on the basis of six pulse signals PLS supplied from six light-receiving pixels P (the light-receiving pixels P1, P3, P5, P7, P9, and P11) ((C) of FIG. 13). This pulse is a pulse corresponding to the reflected light pulse L1. The TDC circuit 40B of the TDC section 23 latches the counter code TDCCODE on the basis of a rising edge of the pulse of this detection signal DETB to thereby generate a code CODEB1.

Next, the detection signal generation circuit 30A of the detection signal generator 22 outputs a pulse starting from a timing t33 as the detection signal DETA on the basis of six pulse signals PLS supplied from the six light-receiving pixels P (the light-receiving pixels P0, P2, P4, P6, P8, and P10) ((B) of FIG. 13). This pulse is a pulse corresponding to the background light LB. The TDC circuit 40A of the TDC section 23 latches the counter code TDCCODE on the basis of a rising edge of the pulse of this detection signal DETA to thereby generate a code CODEA2. In addition, the TDC circuit 40A outputs, as the timing code CODEA, the code CODEA1 generated on the basis of the previous pulse in the detection signal DETA at this timing t33 ((D) of FIG. 13).

Next, the detection signal generation circuit 30B of the detection signal generator 22 outputs a pulse starting from a timing t34 as the detection signal DETB on the basis of six pulse signals PLS supplied from six light-receiving pixels P (the light-receiving pixels P1, P3, P5, P7, P9, and P11) ((C) of FIG. 13). This pulse is a pulse corresponding to the background light LB. The TDC circuit 40B of the TDC section 23 latches the counter code TDCCODE on the basis of a rising edge of the pulse of this detection signal DETB to thereby generate a code CODEB2. In addition, the TDC circuit 40B outputs, as the timing code CODEB, the code CODEB1 generated on the basis of the previous pulse in the detection signal DETB at this timing t34 ((E) of FIG. 13).

Next, the detection signal generation circuit 30A of the detection signal generator 22 outputs a pulse starting from a timing t35 as the detection signal DETA on the basis of six pulse signals PLS supplied from the six light-receiving pixels P (the light-receiving pixels P0, P2, P4, P6, P8, and P10) ((B) of FIG. 13). This pulse is a pulse corresponding to the background light LB. The TDC circuit 40A of the TDC section 23 latches the counter code TDCCODE on the basis of a rising edge of the pulse of this detection signal DETA to thereby generate a code CODEA3. In addition, the TDC circuit 40A outputs, as the timing code CODEA, the code CODEA2 generated on the basis of the previous pulse in the detection signal DETA at this timing t35 ((D) of FIG. 13).

As described above, in this example, the TDC circuit 40A outputs the code CODEA1 representing the detection timing of the reflected light pulse L1 at the timing t33, and the TDC circuit 40B outputs the code CODEA2 representing the detection timing of the reflected light pulse L1 at the timing t34. In other words, the TDC circuits 40A and 40B output the codes CODEA1 and CODEA2 representing the detection timing of one reflected light pulse L1 at timings different from each other.

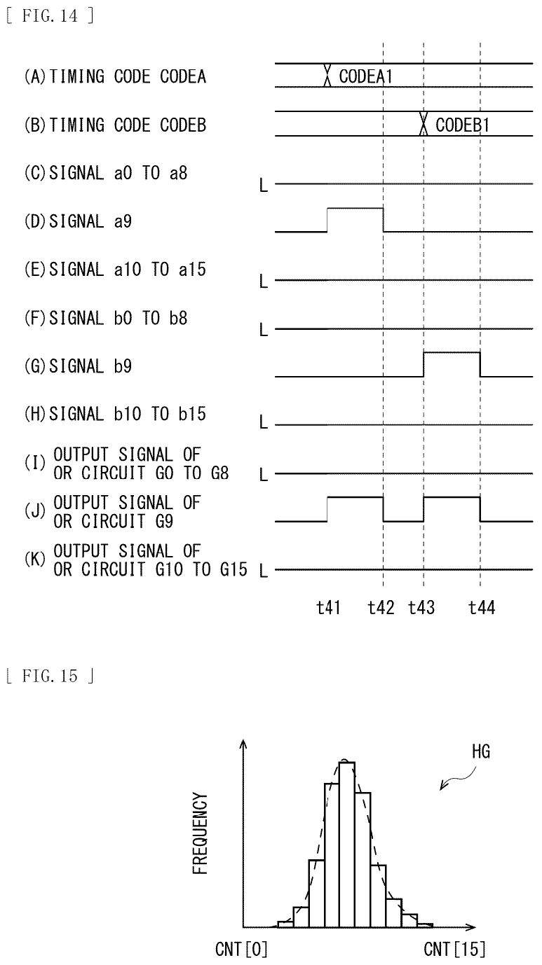

FIG. 14 illustrates an operation example of the histogram generation circuit 50 of the histogram generator 24, where (A) illustrates the timing code CODEA, (B) illustrates the timing code CODEB, (C) to (E) illustrate waveforms of the signals a0 to a15, (F) to (H) illustrate waveforms of the signals b0 to b15, and (I) to (K) illustrate waveforms of the OR circuits G0 to G15.

In this example, the code CODEA1 is supplied as the timing code CODEA at a timing t41, and the code CODEB1 is supplied as the timing code CODEB at a timing t43 ((A) and (B) of FIG. 14).

The decoder 51A decodes the code CODEA1 and outputs a result of the decoding as the signals a0 to a15 at timings t41 to t42 ((C) to (E) of FIG. 14). In this example, the signal a9 is at the high level, and the signals a0 to a8 and a10 to a15 are at the low level.

The decoder 51B decodes the code CODEB1 and outputs a result of the decoding as the signals b0 to b15 at timings t43 to t44 ((E) to (H) of FIG. 14). In this example, the signal b9 is at the high level, and the signals b0 to b8 and b10 to b15 are at the low level. That is, in this example, a code value of the code CODEA1 and a code value of the code CODEB1 are equal to each other.

The OR circuits G0 to G15 respectively determine OR of the signals a0 to a15 and the signal b0 to b15. The output signal of the OR circuit G9 is turned to the high level in accordance with the signal a9 in a period from the timing t41 to the timing t42, and is turned to the high level in accordance with the signal b9 in a period from the timing t43 to the timing t44 ((J) of FIG. 14). The output signals of the OR circuits G0 to G8 and G10 to G15 are maintained at the low level ((I) and (K) of FIG. 14).

Accordingly, the counter CN9 subsequent to the OR circuit G9 performs an increment operation twice on the basis of the output signal of the OR circuit G9 illustrated in (J) of FIG. 14. This increments the count value CNT[9] by two. Thus, the histogram generation circuit 50 generates the histogram HG.

FIG. 15 illustrates an example of the histogram HG. The histogram HG represents the count values CNT[0] to CNT[15] arranged in this order. A horizontal axis indicates a light reception timing, and a vertical axis indicates frequency. A broken line indicates an example of a desired distribution characteristic of the light reception timing determined from the distance between the photodetection system 1 and the measurement object. In this example, the histogram HG substantially coincides with the desired distribution characteristic. The distance calculator 25 is able to calculate the distance between the photodetection system 1 and the measurement object on the basis of a peak position of such a histogram HG, for example.

### Comparative Example

Next, a description is given of workings of the present embodiment in comparison with a photodetector 20R according to a comparative example.

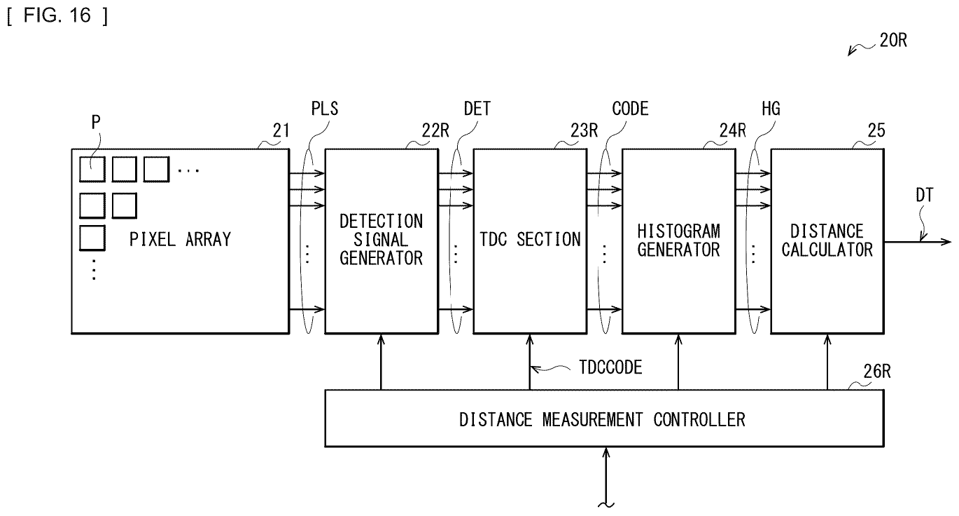

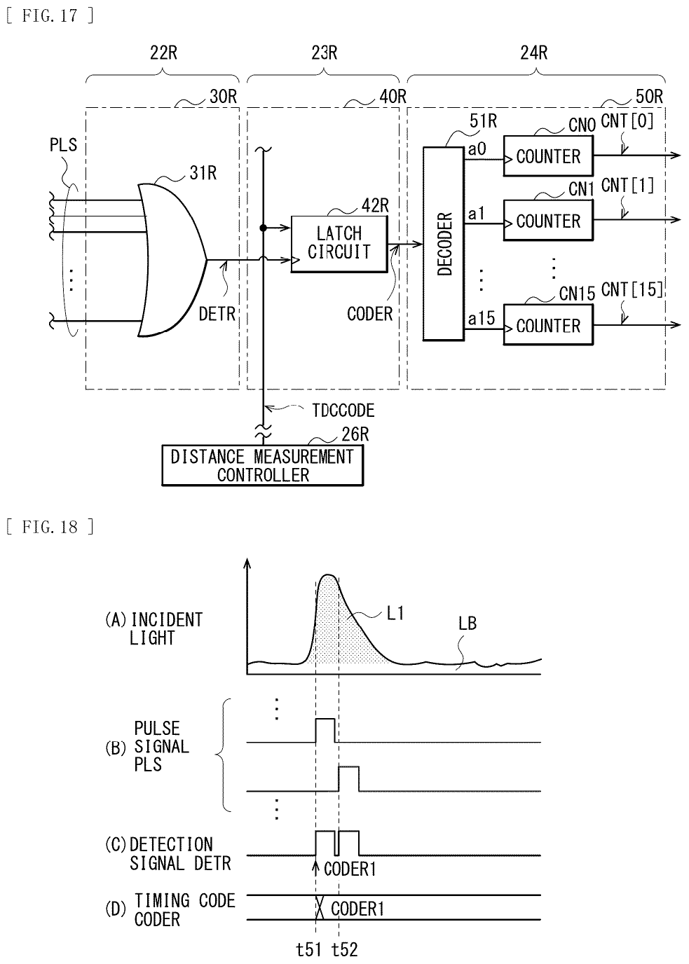

FIG. 16 illustrates a configuration example of the photodetector 20R according to the comparative example. The photodetector 20R includes the pixel array 21, a detection signal generator 22R, a TDC section 23R, a histogram generator 24R, the distance calculator 25, and a distance measurement controller 26R. FIG. 17 illustrates a configuration example of the detection signal generator 22R, the TDC section 23R, and the histogram generator 24R.

The detection signal generator 22R includes a detection signal generation circuit 30R. The detection signal generation circuit 30R is configured to generate a detection signal DET corresponding to results of light reception by twelve light-receiving pixels P on the basis of twelve pulse signals PLS related to the twelve light-receiving pixels P. The detection signal generation circuit 30R includes an OR circuit 31R. The OR circuit 31R is configured to generate a detection signal DETR by performing an OR operation on the basis of twelve pulse signals PLS supplied from the twelve light-receiving pixels P (the light-receiving pixels P0 to P11) illustrated in FIG. 9.

The TDC section 23R includes a TDC circuit 40R. The TDC circuit 40R is configured to generate a timing code CODER corresponding to detection timings of the reflected light pulse L1 in the twelve light-receiving pixels P on the basis of the detection signal DETR related to the twelve light-receiving pixels P. The TDC circuit 40R includes a latch circuit 42R. The latch circuit 42R is configured to latch the counter code TDCCODE supplied from the distance measurement controller 26R on the basis of the detection signal DETR and outputs the latched code as the timing code CODER.

The histogram generator 24R includes a histogram generation circuit 50R. The histogram generation circuit 50R is configured to generate the histogram HG on the basis of the timing code CODER related to the twelve light-receiving pixels P. The histogram generation circuit 50R includes a decoder 51R, and a plurality of counters (sixteen counters CN0 to CN15 in this example). The decoder 51R is configured to generate a plurality of signals (sixteen signals a0 to a15 in this example) by decoding the timing code CODER of a plurality of bits (four bits in this example). The counters CN0 to CN15 are configured to respectively generate the count values CNT[0] to CNT[15] by performing a counting operation on the basis of rising edges of the signals a0 to a15.

The distance measurement controller 26R (FIG. 16) is configured to control operations of the detection signal generator 22R, the TDC section 23R, the histogram generator 24R, and the distance calculator 25 on the basis of an instruction from the controller 14 (FIG. 1).

FIG. 18 illustrates an operation example of the TDC section 23R, where (A) illustrates an optical waveform of incident light on the pixel array 21, (B) illustrates a waveform of the pulse signal PLS, (C) illustrates a waveform of the detection signal DETR, and (D) illustrates the timing code CODER. In this example, the reflected light pulse L1 enters the pixel array 21 around at a timing t51 ((a) of FIG. 18).

One light-receiving pixel P of the twelve light-receiving pixels P outputs a pulse starting from the timing t51 as the pulse signal PLS, and one other light-receiving pixel P outputs a pulse starting from a timing t54 as the pulse signals PLS ((B) of FIG. 18). These pulses are pulses corresponding to the reflected light pulse L1. The detection signal generation circuit 30R of the detection signal generator 22R outputs the pulse starting from the timing t51 and the pulse starting from the timing t52 as the detection signal DETR on the basis of these pulse signals PLS ((C) of FIG. 18).

The TDC circuit 40R of the TDC section 23R latches the counter code TDCCODE on the basis of a rising edge of the pulse starting from the timing t51 in this detection signal DETR to thereby generate a code CODER1 ((C) of FIG. 18). Thereafter, the TDC circuit 40R outputs this code CODER1 as the timing code CODER ((D) of FIG. 18).

In this example, the detection signal DETR includes a pulse starting from a timing t52 directly after the pulse starting from the timing t51, but an interval between these pulses is narrow. As a result, the TDC circuit 40R is not operable on the basis of the pulse starting from the timing t52. Accordingly, the TDC circuit 40R outputs only the code CODER1 related to the pulse starting from the timing t51 as the timing code CODER.

The histogram generation circuit 50R of the histogram generator 24R generates the histogram HG on the basis of such a timing code CODER.

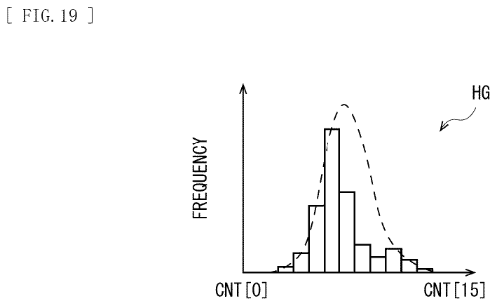

FIG. 19 illustrates an example of the histogram HG generated by the photodetector 20R according to the comparative example. A broken line indicates an example of a desired distribution characteristic of the light reception timing determined from the distance between the photodetection system 1 and the measurement object. In this example, the histogram HG does not coincide with the desired distribution characteristic, and a peak position of the histogram HG is shifted to the left from a peak position of the desired distribution characteristic. That is, as illustrated in FIG. 18, timing information related to the pulse starting from the timing t52 is lost; therefore, some data on the right in the histogram HG is missing. As a result, the peak position of the histogram HG is shifted to the left from the peak position of the desired distribution characteristic. The distance calculator 25 calculates the distance between the photodetection system 1 and the measurement object on the basis of the peak position of the histogram HG, for example. Accordingly, in a photodetection system including such a photodetector 20R, distance detection accuracy decreases.

In contrast, in the photodetection system 1 according to the present embodiment, as illustrated in FIGS. 13 and 14, the photodetector 20 is able to generate the histogram HG on the basis of both of the code CODEA1 related to the pulse starting from the timing t31 and the code CODEB1 related to the pulse starting from the timing t32. This allows the photodetection system 1 to obtain a more accurate histogram HG as illustrated in FIG. 15, which makes it possible to enhance distance detection accuracy.

Thus, the photodetection system 1 includes the plurality of light-receiving pixels P including a plurality of first light-receiving pixels (the light-receiving pixels P0, P2, P4, P6, P8, and P10) and a plurality of second light-receiving pixels (the light-receiving pixels P1, P3, P5, P7, P9, and P11). The plurality of light-receiving pixels P each detects the reflected light pulse L1 and generates the pulse signal PLS including the pulse corresponding to the reflected light pulse L1. The plurality of first light-receiving pixels is provided at positions not adjacent to each other. The plurality of second light-receiving pixels is provided at positions not adjacent to each other. A first OR circuit (the OR circuit 31A) and a first timing code generation circuit (the TDC circuit 40A) are provided. The first OR circuit generates a first detection signal (the detection signal DETA) by performing an OR operation of a plurality of pulse signals PLS generated by the plurality of first light-receiving pixels. The first timing code generation circuit generates a first timing code (the timing code CODEA) corresponding to a timing when a pulse included in the first detection signal occurs. A second OR circuit (the OR circuit 31B) and a second timing code generation circuit (the TDC circuit 40B) are provided. The second OR circuit generates a second detection signal (the detection signal DETB) by performing an OR operation of a plurality of pulse signals PLS generated by the plurality of second light-receiving pixels. The second timing code generation circuit generates a second timing code (the timing code CODEB) corresponding to a timing when a pulse included in the second detection signal occurs. A first histogram generation circuit (the histogram generation circuit 50) is provided that generates first signals (the signals a0 to a15) including a plurality of bit signals by decoding the first timing code, and generates second signals (the signals b0 to b15) including a plurality of bit signals by decoding the second timing code, synthesizes the first signals and the second signals to generate first composite signals, and generates a first histogram (the histogram HG) on the basis of the first composite signals. Accordingly, in the photodetection system 1, for example, as illustrated in FIGS. 13 and 14, it is possible to generate the histogram HG on the basis of both of the code CODEA1 related to the pulse starting from the timing t31 and the code CODEB1 related to the pulse starting from the timing t32, which makes it possible to obtain a more accurate histogram HG. Thus, it is possible to enhance detection accuracy.

In addition, in the photodetection system 1, the first timing code generation circuit (the TDC circuit 40A) generates the first timing code (the timing code CODEA) corresponding to the timing when the pulse included in the first detection signal (the detection signal DETA) occurs, and outputs the first timing code at a timing when a pulse after this pulse in the first detection signal occurs. In addition, the second timing code generation circuit (the TDC circuit 40B) generates the second timing code (the timing code CODEB) corresponding to the timing when the pulse included in the second detection signal (the detection signal DETB) occurs, and outputs the second timing code at a timing when a pulse after this pulse in the second detection signal occurs. Accordingly, as illustrated in FIG. 13, the TDC circuits 40A and 40B are able to output the timing codes CODEA and CODEB on the basis of a pulse corresponding to the background light LB; therefore, a timing when the timing code CODEA is outputted and a timing when the timing code CODEB is outputted tend to be different from each other. Accordingly, in the photodetection system 1, as illustrated in FIG. 14, it is possible to generate the histogram HG on the basis of both of the timing code CODEA and the timing code CODEB, which makes it possible to obtain a more accurate histogram HG. Thus, it is possible to enhance detection accuracy.

### Effects

As described above, in the present embodiment, the plurality of light-receiving pixels P including the plurality of first light-receiving pixels and the plurality of second light-receiving pixels is provided. The plurality of light-receiving pixels each detects the reflected light pulse and generates the pulse signal including the pulse corresponding to the reflected light pulse. The plurality of first light-receiving pixels is provided at positions not adjacent to each other. The plurality of second light-receiving pixels is provided at positions not adjacent to each other. The first OR circuit and the first timing code generation circuit are provided. The first OR circuit generates the first detection signal by performing an OR operation of a plurality of pulse signals generated by the plurality of first light-receiving pixels. The first timing code generation circuit generates the first timing code corresponding to a timing when a pulse included in the first detection signal occurs. The second OR circuit and the second timing code generation circuit are provided. The second OR circuit generates the second detection signal by performing an OR operation of a plurality of pulse signals generated by the plurality of second light-receiving pixels. The second timing code generation circuit generates the second timing code corresponding to a timing when a pulse included in the second detection signal occurs. The first histogram generation circuit is provided that generates the first signals including a plurality of bit signals by decoding the first timing code and generates the second signals including a plurality of bit signals by decoding the second timing code, synthesizes the first signals and the second signals to generate the first composite signals, and generates the first histogram on the basis of the first composite signals. Thus, it is possible to enhance detection accuracy.

In addition, in the present embodiment, the first timing code generation circuit generates the first timing code corresponding to the timing when the pulse included in the first detection signal occurs, and outputs the first timing code at a timing when a pulse after this pulse in the first detection signal occurs. In addition, the second timing code generation circuit generates the second timing code corresponding to the timing when the pulse included in the second detection signal occurs, and outputs the second timing code at a timing when a pulse after this pulse in the second detection signal occurs. Thus, it is possible to enhance detection accuracy.

### Modification Example 1

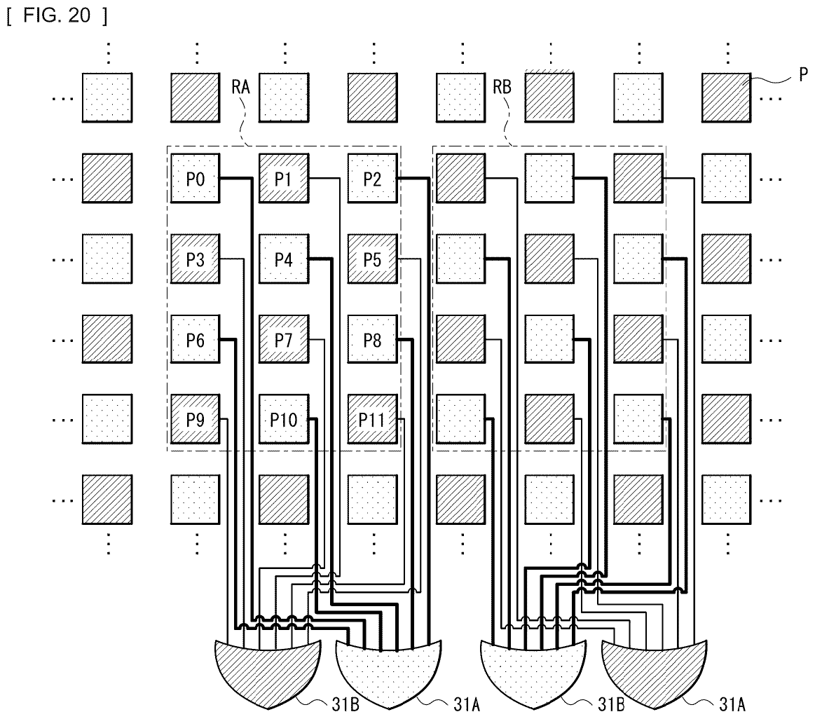

In the embodiment described above, as illustrated in FIG. 9, an arrangement pattern of the light-receiving pixels P coupled to the OR circuit 31A and the light-receiving pixels P coupled to the OR circuit 31B in twelve light-receiving pixels P is the same as an arrangement pattern in other twelve light-receiving pixels P, but the arrangement pattern is not limited thereto. Instead of this, for example, as illustrated in FIG. 20, an arrangement pattern of the light-receiving pixels P coupled to the OR circuit 31A and the light-receiving pixels P coupled to the OR circuit 31B in twelve light-receiving pixels P may be different from an arrangement pattern in other twelve light-receiving pixels P. In an example in FIG. 20, for example, the light-receiving pixel P at the upper left among twelve light-receiving pixels P in a region RA is coupled to the OR circuit 31A, and the light-receiving pixel P at the upper left among twelve light-receiving pixels P in a region RB is coupled to the OR circuit 31B.

### Modification Example 2

In the embodiment described above, twelve light-receiving pixels P are coupled to two OR circuits 31A and 31B, but this is not limitative. The present modification example is described in detail below with reference to some examples.

First, a description is given of an example in which twelve light-receiving pixels P are coupled to four OR circuits.

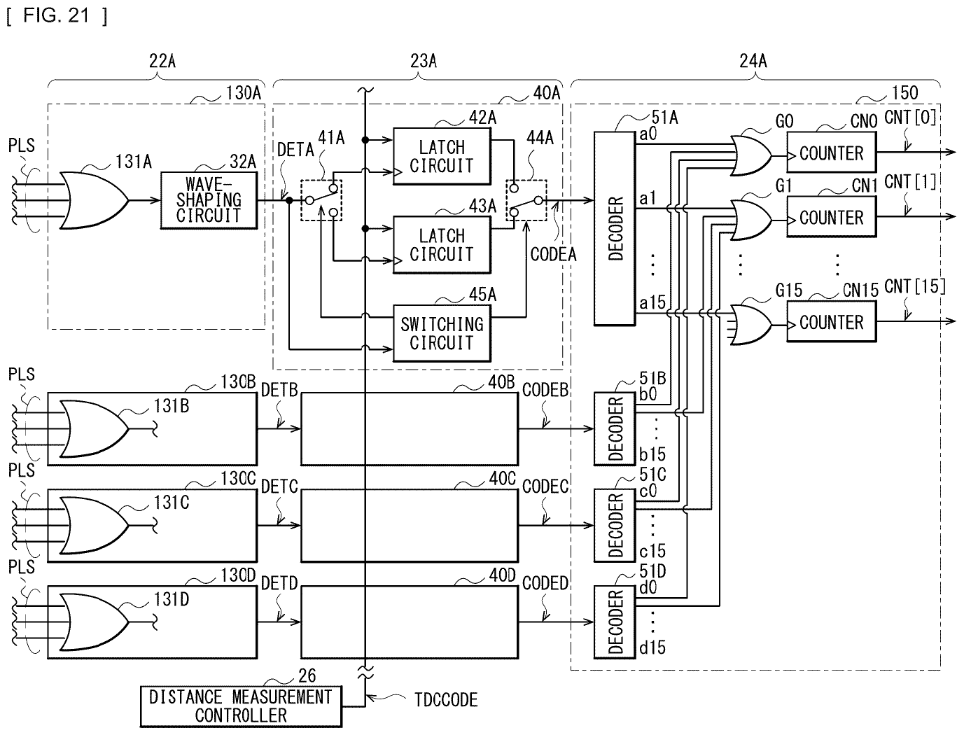

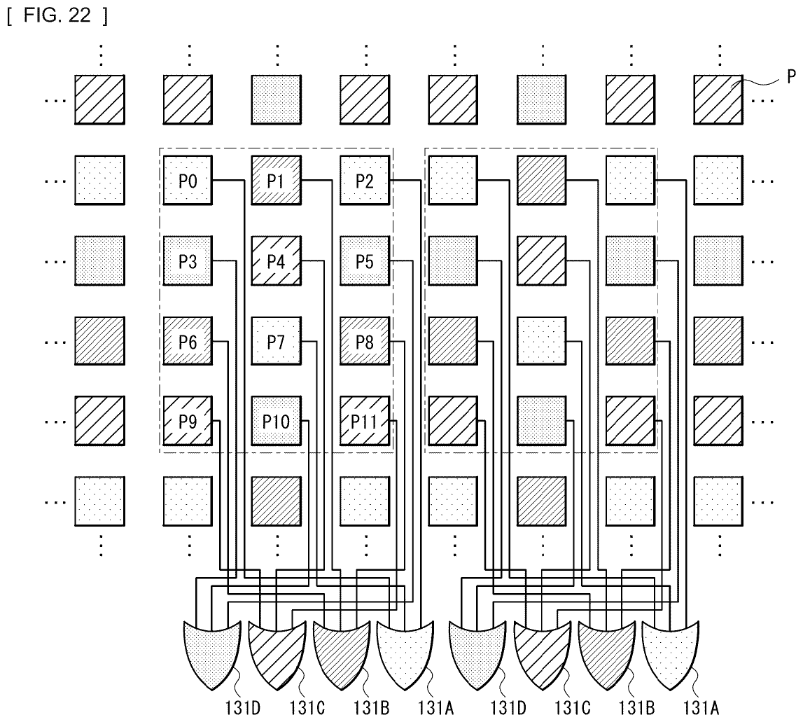

FIG. 21 illustrates a configuration example of a detection signal generator 22A, a TDC section 23A, and a histogram generator 24A according to the present modification example. FIG. 22 illustrates an example of coupling between twelve light-receiving pixels P and subsequent-stage circuits.

The detection signal generator 22A includes detection signal generation circuits 130A, 130B, 130C, and 130D. The detection signal generation circuits 130A, 130B, 130C, and 130D are configured to generate detection signals DETA, DETB, DETC, and DETD corresponding to results of light reception by the twelve light-receiving pixels P on the basis of twelve pulse signals PLS related to the twelve light-receiving pixels P. The detection signal generation circuits 130A, 130B, 130C, and 130D respectively include OR circuits 131A, 131B, 131C, and 131D. In this example, the twelve light-receiving pixels P (the light-receiving pixels P0 to P11) arranged in a 3×4 pattern are coupled to four OR circuits 131A to 131D. The light-receiving pixels P0, P2, and P7 are provided at positions not adjacent to each other in the lateral direction and the longitudinal direction. The light-receiving pixels P0, P2, and P7 are coupled to the OR circuit 131A. The light-receiving pixels P1, P6, and P8 are provided at positions not adjacent to each other in the lateral direction and the longitudinal direction. The light-receiving pixels P1, P6, and P8 are coupled to the OR circuit 131B. The light-receiving pixel P4, P9, and P11 are provided at positions not adjacent to each other in the lateral direction and the longitudinal direction. The light-receiving pixels P4, P9, and P11 are coupled to the OR circuit 131C. The light-receiving pixels P3, P5, and P10 are provided at positions not adjacent to each other in the lateral direction and the longitudinal direction. The light-receiving pixels P3, P5, and P10 are coupled to the OR circuit 131D.

The TDC section 23A includes TDC circuits 40A, 40B, 40C, and 40D. The TDC circuits 40A, 40B, 40C, and 40D are configured to generate timing codes CODEA, CODEB, CODEC, and CODED corresponding to detection timings of the reflected light pulse L1 in the twelve light-receiving pixels P on the basis of the detection signals DETA, DETB, DETC, and DETD related to the twelve light-receiving pixels P.

The histogram generator 24A includes a histogram generation circuit 150. The histogram generation circuit 150 is configured to generate the histogram HG on the basis of the timing codes CODEA, CODEB, CODEC, and CODED related to the twelve light-receiving pixels P. The histogram generation circuit 150 includes decoders 51A, 51B, 51C, and 51D and OR circuits G0 to G15. The decoder 51A is configured to generate a plurality of signals (the sixteen signals a0 to a15 in this example) by decoding the timing code CODEA of a plurality of bits (four bits in this example). The decoder 51B is configured to generate a plurality of signals (the sixteen signals b0 to b15 in this example) by decoding the timing code CODEB of a plurality of bits (four bits in this example). The decoder 51C is configured to generate a plurality of signals (sixteen signals c0 to c15 in this example) by decoding the timing code CODEC of a plurality of bits (four bits in this example). The decoder 51D is configured to generate a plurality of signals (sixteen signals d0 to d15 in this example) by decoding the timing code CODED of a plurality of bits (four bits in this example). The OR circuit G0 is configured to determine OR of the signal a0 supplied from the decoder 51A, the signal b0 supplied from the decoder 51B, the signal c0 supplied from the decoder 51C, and the signal d0 supplied from the decoder 51D. The OR circuit G1 is configured to determine OR of the signal a1 supplied from the decoder 51A, the signal b1 supplied from the decoder 51B, the signal c1 supplied from the decoder 51C, and the signal d1 supplied from the decoder 51D. The same applies to the OR circuits G2 to G15. This causes the OR circuits G0 to G15 to synthesize the signals a0 to a15 supplied from the decoder 51A, the signals b0 to b15 supplied from the decoder 51B, the signals c0 to c15 supplied from the decoder 51C, and the signals d0 to d15 supplied from the decoder 51D.

Next, a description is given of an example in which sixteen light-receiving pixels P are coupled to four OR circuits.

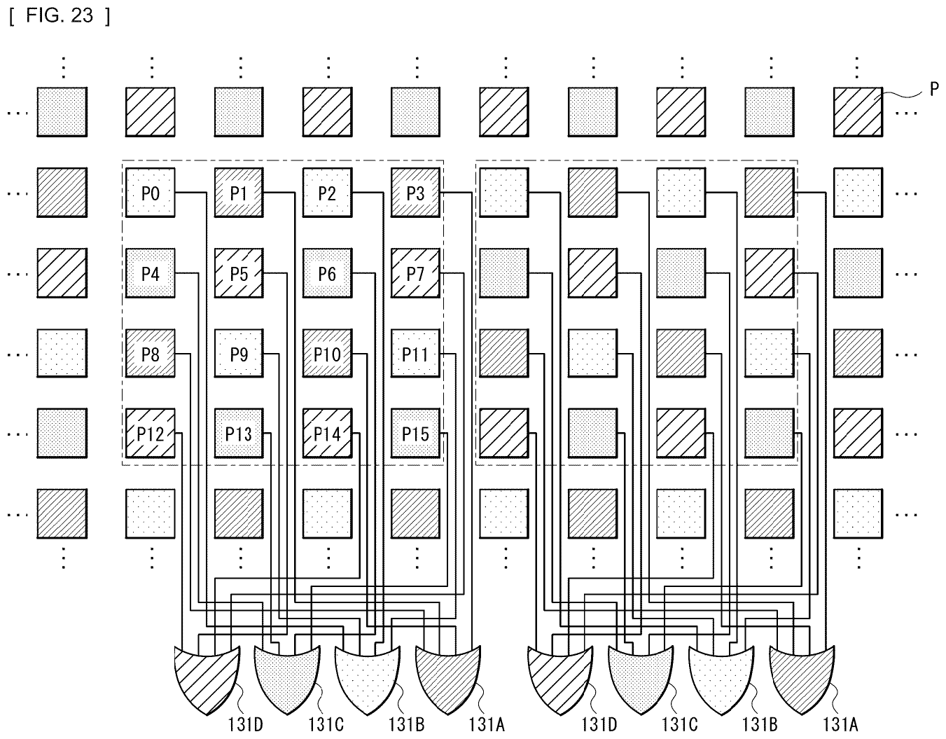

FIG. 23 illustrates an example of coupling between sixteen light-receiving pixels P and subsequent-stage circuits according to the present modification example. In this example, the sixteen light-receiving pixels P (light-receiving pixels P0 to P15) arranged in a 4×4 pattern are coupled to four OR circuits 131A to 131D. The light-receiving pixels P1, P3, P8, and P10 are provided at positions not adjacent to each other in the lateral direction and the longitudinal direction. The light-receiving pixels P1, P3, P8, and P10 are coupled to the OR circuit 131A. The light-receiving pixels P0, P2, P9, and P11 are provided at positions not adjacent to each other in the lateral direction and the longitudinal direction. The light-receiving pixels P0, P2, P9, and P11 are coupled to the OR circuit 131B. The light-receiving pixels P4, P6, P13, and P15 are provided at positions not adjacent to each other in the lateral direction and the longitudinal direction. The light-receiving pixels P4, P6, P13, and P15 are coupled to the OR circuit 131C. The light-receiving pixels P5, P7, P12, and P14 are provided at positions not adjacent to each other in the lateral direction and the longitudinal direction. The light-receiving pixels P5, P7, P12, and P14 are coupled to the OR circuit 131D.

Next, a description is given of an example in which the detection signal generator is not provided and two light-receiving pixels P are coupled to two TDC circuits.

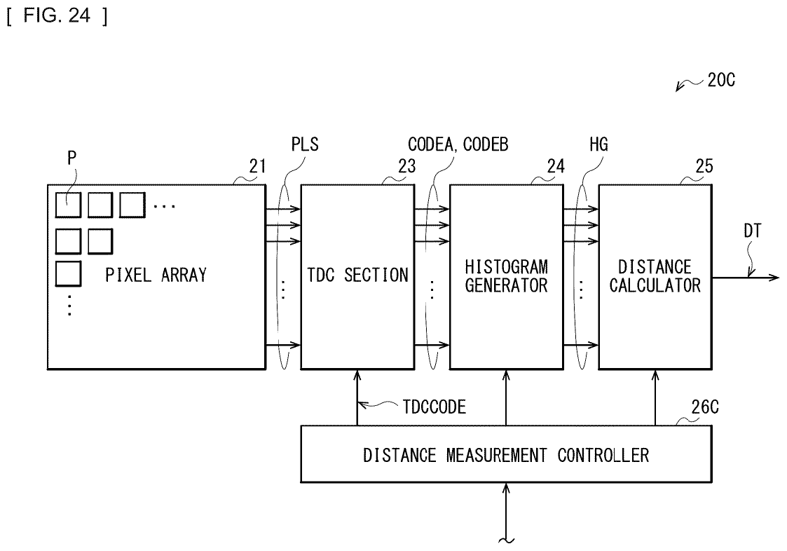

FIG. 24 illustrates a configuration example of a photodetector 20C according to the present modification example. The photodetector 20C includes the pixel array 21, the TDC section 23, the histogram generator 24, the distance calculator 25, and a distance measurement controller 26C.

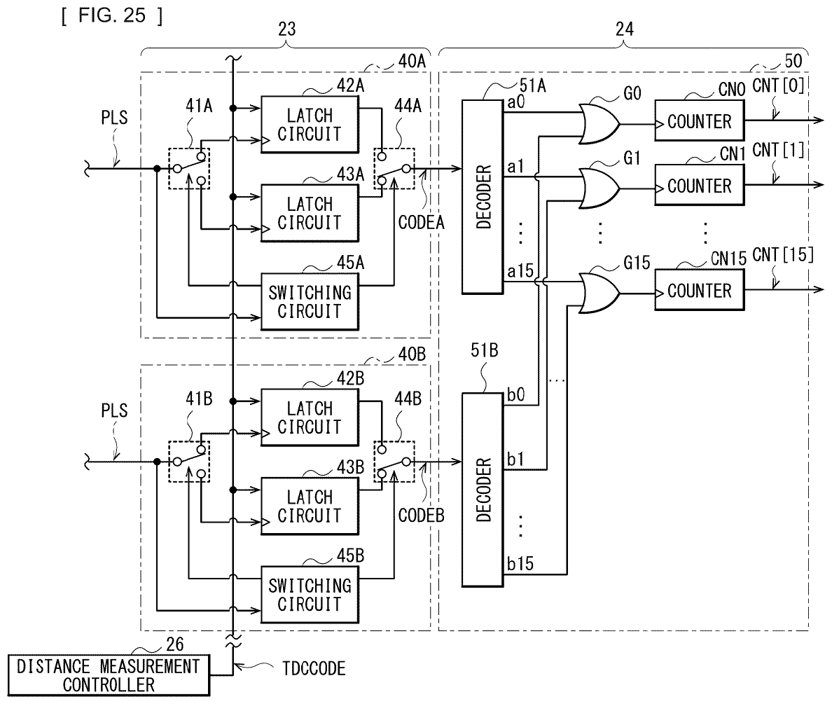

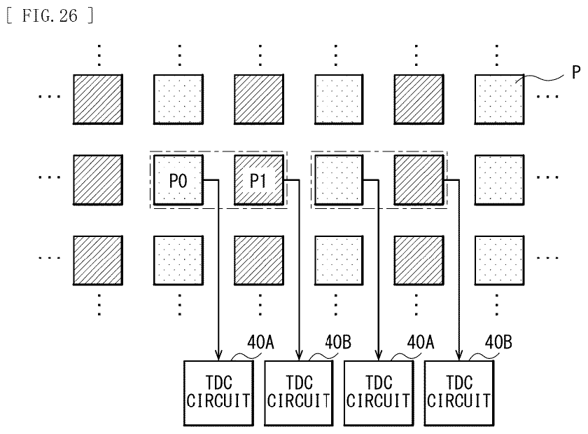

FIG. 25 illustrates a configuration example of the TDC section 23 and the histogram generator 24. FIG. 26 illustrates an example of coupling between two light-receiving pixels P and subsequent-stage circuits.

The TDC section 23 includes the TDC circuits 40A and 40B. The TDC circuits 40A and 40B are configured to generate the timing codes CODEA and CODEB corresponding to detection timings of the reflected light pulse L1 in the two light-receiving pixels P on the basis of two pulse signals PLS related to the two light-receiving pixels P. In this example, the two light-receiving pixels P (the light-receiving pixels P0 and P1) arranged in a 2×1 pattern are coupled to two TDC circuits 40A and 40B. Specifically, the light-receiving pixel P0 is coupled to the TDC circuit 40A, and the light-receiving pixel P1 is coupled to the TDC circuit 40B. It is to be noted that this is not limitative, and the two light-receiving pixels P arranged in, for example, a 1×2 pattern may be coupled to the two TDC circuits 40A and 40B.

### Modification Example 3

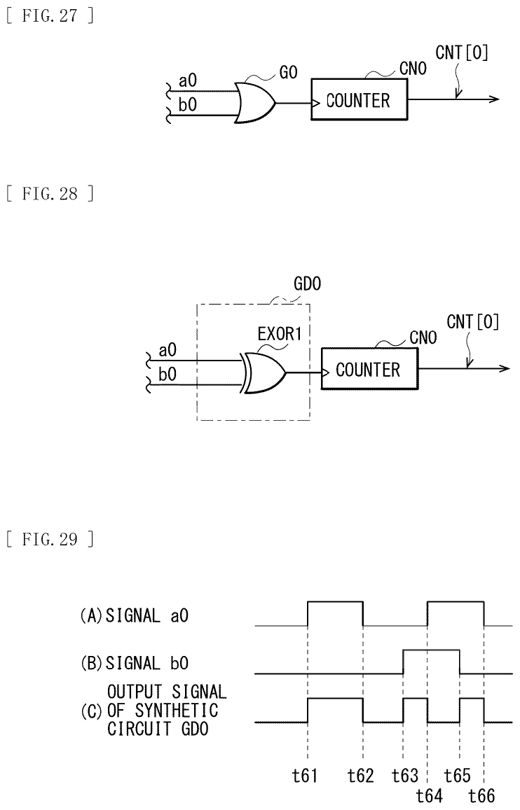

In the embodiment described above, the histogram generation circuit 50 uses, for example, the OR circuit G0 as a synthetic circuit as illustrated in FIG. 27 to synthesize the signal a0 and the signal b0, but this is not limitative. The present modification example is described in detail below with reference to some examples.

FIG. 28 illustrates an example of a synthetic circuit GD0 according to the present modification example. In addition to the synthetic circuit GD0, FIG. 28 also illustrates the counter CN0 subsequent to this synthetic circuit GD0. The synthetic circuit GD0 synthesizes the signal a0 and the signal b0. The synthetic circuit GD0 includes an exclusive OR circuit EXOR1. The exclusive OR circuit EXOR1 is configured to determine exclusive OR of the signal a0 supplied from the decoder 51A and the signal b0 supplied from the decoder 51B. The synthetic circuit GD0 supplies an output signal of the exclusive OR circuit EXOR1 to the counter CN0.

With this configuration, the synthetic circuit GD0 outputs a signal that is at the high level in a case where only one of the signal a0 and the signal b0 is at the high level and the other one is at the low level, and outputs a signal that is at the low level in other cases.

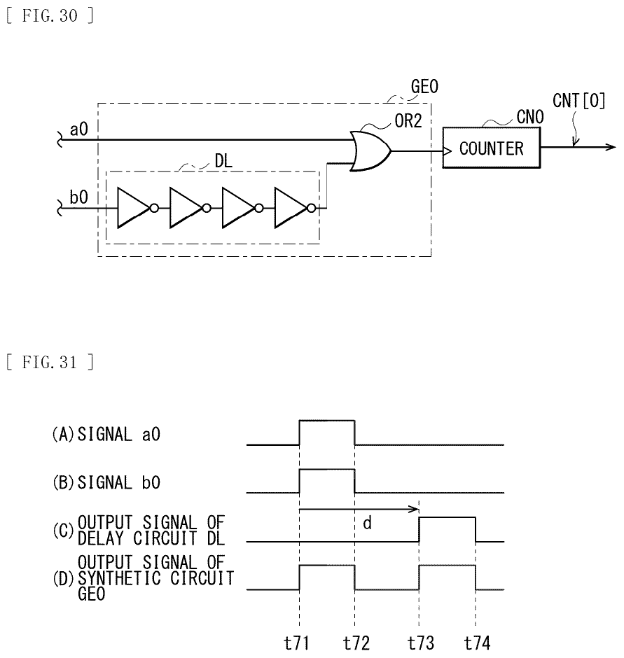

FIG. 29 illustrates an operation example of the synthetic circuit GD0, where (A) illustrates a waveform of the signal a0, (B) illustrates waveform of a signal b0, and (C) illustrates a waveform of an output signal of the synthetic circuit GD0. In this example, the signal a0 changes from the low level to the high level at a timing t61, changes from the high level to the low level at a timing t62, changes from the low level to the high level at a timing t64, and changes from the high level to the low level at a timing t66 ((A) of FIG. 29). The signal b0 changes from the low level to the high level at a timing t63, and changes from the high level to the low level at a timing t65 ((B) of FIG. 29). That is, the signal a0 includes a pulse starting from the timing t61 and a pulse starting from the timing t64, and the signal b0 includes a pulse starting from the timing t63. A part of a pulse period of the pulse of the signal b0 starting from the timing t63 and a part of a pulse period of the pulse of the signal a0 starting from the timing t64 overlap each other.

The synthetic circuit GD0 changes the output signal from the low level to the high level at the timing t61, and changes the output signal from the high level to the low level at the timing t62 ((C) of FIG. 29). In addition, the synthetic circuit GD0 changes the output signal from the low level to the high level at the timing t63, and changes the output signal from the high level to the low level at the timing t64. In addition, the synthetic circuit GD0 changes the output signal from the low level to the high level at the timing t65, and changes the output signal from the high level to the low level at the timing t66. Thus, the output signal of the synthetic circuit GD0 includes a pulse starting from the timing t61, a pulse starting from the timing t63, and a pulse starting from the timing t65. That is, the signals a0 and b0 include three pulses; therefore, the output signal of the synthetic circuit GD0 includes three pulses.

The counter CN0 subsequent to the synthetic circuit GD0 performs an increment operation three times on the basis of the output signal of the synthetic circuit GD0 illustrated in (C) of FIG. 29. This increments the count value CNT[0] by three.

FIG. 30 illustrates an example of another synthetic circuit GE0 according to the present modification example. The synthetic circuit GE0 synthesizes the signal a0 and the signal b0. The synthetic circuit GE0 includes a delay circuit DL and an OR circuit OR2. The delay circuit DL is configured to delay the signal b0 supplied from the decoder 51B by a predetermined time in this example. The delay circuit DL in this example includes a plurality of (four in this example) inverters. The OR circuit OR2 determines OR of the signal a0 supplied from the decoder 51A and the output signal of the delay circuit DL.

FIG. 31 illustrates an operation example of the synthetic circuit GE0, where (A) illustrates the waveform of the signal a0, (B) illustrates the waveform of the signal b0, (C) illustrates a waveform of an output signal of the delay circuit DL, and (D) illustrates a waveform of an output signal of the synthetic circuit GE0. In this example, the signal a0 changes from the low level to the high level at a timing t71, and changes from the high level to the low level at a timing t72 ((A) of FIG. 31). The signal b0 changes from the low level to the high level at the timing t71, and changes from the high level to the low level at the timing t72 ((B) of FIG. 31). That is, each of the signals a0 and b0 includes a pulse starting from the timing t71.

The delay circuit DL delays the signal b0 by a predetermined time d. Accordingly, the delay circuit DL changes the output signal from the low level to the high level at a timing t73, and changes the output signal from the high level to the low level at a timing t74 ((C) of FIG. 31).

The synthetic circuit GE0 changes the output signal from the low level to the high level at the timing t71, changes the output signal from the high level to the low level at the timing t72, changes the output signal from the low level to the high level at the timing t73, and changes the output signal from the high level to the low level at the timing t74 ((D) of FIG. 31). Thus, the output signal of the synthetic circuit GE0 includes a pulse starting from the timing t71 and a pulse starting from the timing t73. That is, the signals a0 and b0 include two pulses; therefore, the output signal of the synthetic circuit GE0 includes two pulses.

The counter CN0 subsequent to the synthetic circuit GE0 performs an increment operation twice on the basis of the output signal of the synthetic circuit GE0 illustrated in (D) of FIG. 30. This increments the count value CNT[0] by two.

It is to be noted that, in this example, the delay circuit DL delays the signal b0 supplied from the decoder 51B by the predetermined time, but this is not limitative. Instead of this, for example, the delay circuit DL may delay the signal a0 supplied from the decoder 51A by a predetermined time.

### Modification Example 4

In the embodiment described above, a plurality of histograms HG is generated on the basis of results of light reception by all of the plurality of light-receiving pixels P in the pixel array 21, but this is not limitative. Instead of this, for example, a predetermined number of light-receiving pixels P may be selected from among the plurality of light-receiving pixels P in the pixel array to generate one histogram HG on the basis of results of light reception by the predetermined number of selected light-receiving pixels P. The present modification example is described in detail below.

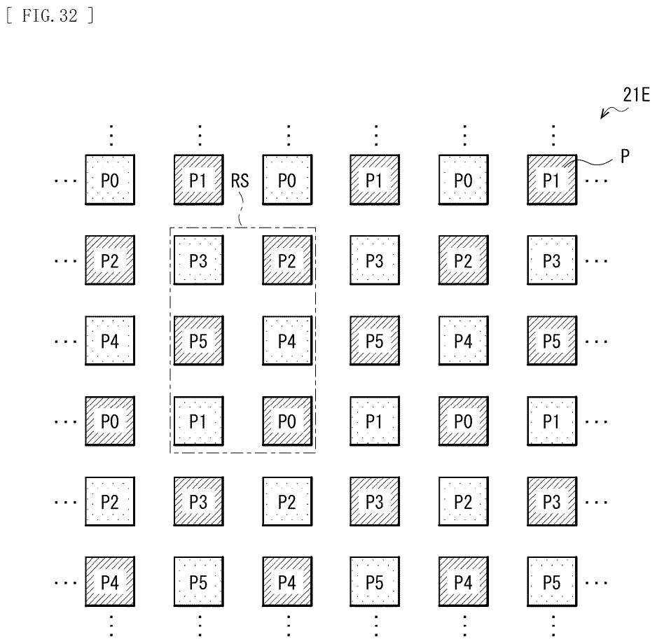

FIG. 32 illustrates a configuration example of a pixel array 21E according to the present modification example. The pixel array 21E includes a plurality of light-receiving pixels P1, a plurality of light-receiving pixels P2, a plurality of light-receiving pixels P3, a plurality of light-receiving pixels P4, a plurality of light-receiving pixels P5, and a plurality of light-receiving pixels P6. The light-receiving pixels P0, P3, and P4 are provided at positions not adjacent to each other in the lateral direction and the longitudinal direction. The light-receiving pixels P1, P2, and P5 are provided at positions not adjacent to each other in the lateral direction and the longitudinal direction. In this example, six (2×3) light-receiving pixels P are selected from among the plurality of light-receiving pixels P in the pixel array 21. In this example, six light-receiving pixels P1 to P6 in a region RS are selected.

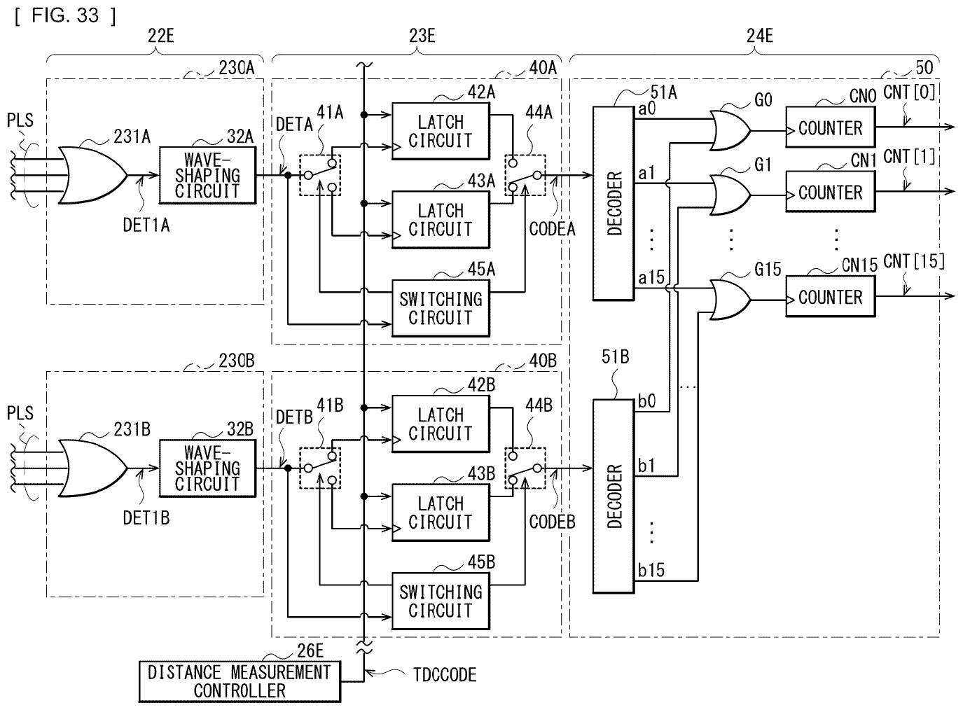

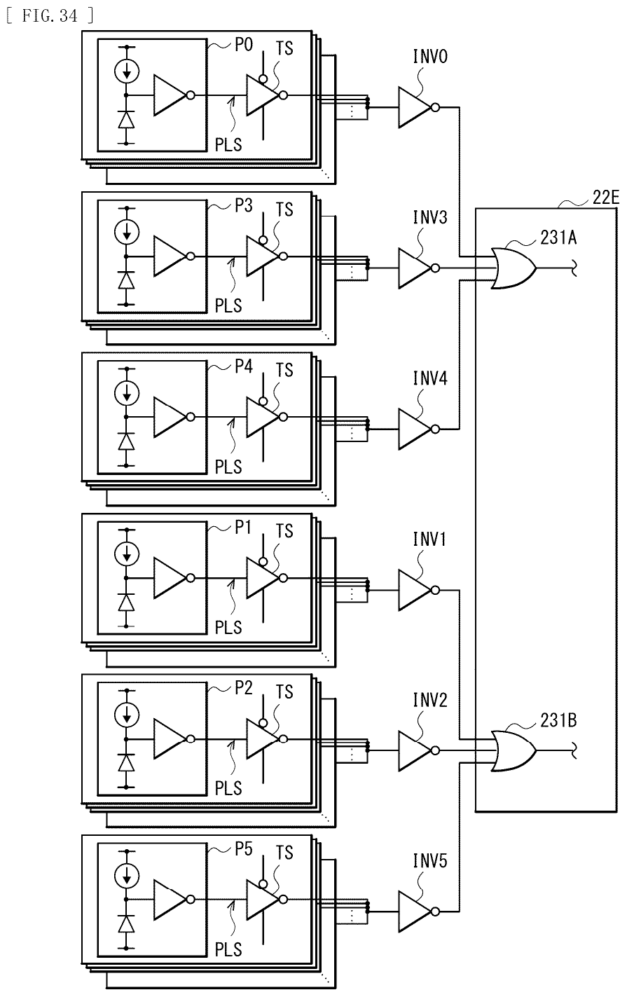

FIG. 33 illustrates a configuration example of a detection signal generator 22E, a TDC section 23E, and a histogram generator 24E according to the present modification example. FIG. 34 illustrates coupling between the plurality of light-receiving pixels P in the pixel array 21E and subsequent-stage circuits.

The detection signal generator 22E includes two detection signal generation circuits 230A and 230B. The detection signal generation circuit 230A includes an OR circuit 231A. The detection signal generation circuit 230B includes an OR circuit 231B.

As illustrated in FIG. 34, a tristate inverter TS is provided subsequent to each of the light-receiving pixels P0 to P6. The tristate inverter TS operates as an inverter, or sets an output impedance to a high impedance, on the basis of, for example, a control signal from the distance measurement controller 26E according to the present modification example. Output terminals of a plurality of tristate inverters TS subsequent to the plurality of light-receiving pixels P0 are coupled to each other, and are coupled to an input terminal of the inverter INV0. Output terminals of a plurality of tristate inverters TS subsequent to the plurality of light-receiving pixels P3 are coupled to each other, and are coupled to an input terminal of the inverter INV3. Output terminals of a plurality of tristate inverters TS subsequent to the plurality of light-receiving pixels P4 are coupled to each other, and are coupled to an input terminal of the inverter INV4. Output terminals of a plurality of tristate inverters TS subsequent to the plurality of light-receiving pixels P1 are coupled to each other, and are coupled to an input terminal of the inverter INV1. Output terminals of a plurality of tristate inverters TS subsequent to the plurality of light-receiving pixels P2 are coupled to each other, and are coupled to an input terminal of the inverter INV2. Output terminals of a plurality of tristate inverters TS subsequent to the plurality of light-receiving pixels P5 are coupled to each other, and are coupled to an input terminal of the inverter INV5. Output terminals of the inverters INV0, INV3, and INV4 are coupled to the OR circuit 231A. Output terminals of the inverters INV1, INV2, and INV5 are coupled to the OR circuit 231B.

With this configuration, the tristate inverters TS coupled to the six light-receiving pixels P1 to P6 included in the region RS operate as inverters and the other tristate inverters TS set the output impedance to the high impedance, on the basis of, for example, a control signal from the distance measurement controller 26E. Accordingly, three pulse signals corresponding to three pulse signals PLS generated by the light-receiving pixels P0, P3, and P4 of the six light-receiving pixels P1 to P6 included in the region RS are supplied to the OR circuit 231A, and three pulse signals corresponding to three pulse signals PLS generated by the light-receiving pixels P1, P2, and P5 are supplied to the OR circuit 231B.

The TDC section 23E includes two TDC circuits 40A and 40B. The histogram generator 24E includes one histogram generation circuit 50.

In this example, the light-receiving pixel P has a circuit configuration illustrated in FIG. 6, but the circuit configuration of the light-receiving pixel P is not limited thereto. Instead of this, for example, the light-receiving pixel P may have a circuit configuration illustrated in FIG. 4. This makes it possible to shorten dead time. In addition, for example, the flip-flop circuit FF1 and the inverter IV2 illustrated in FIG. 4 may be provided in each of a path that couples the inverter INV0 and the OR circuit 231A, a path that couples the inverter INV3 and the OR circuit 231A, a path that couples the inverter INV4 and the OR circuit 231A, a path that couples the inverter INV1 and the OR circuit 231B, a path that couples the inverter INV2 and the OR circuit 231B, and a path that couples the inverter INV5 and the OR circuit 231B. In this case, it is possible to reduce the number of the flip-flop circuits FF1 and the number of the inverters IV2 as compared with a case where the flip-flop circuit FF1 and the inverter IV2 are provided in each of the light-receiving pixels P. This makes it possible to reduce a circuit area.

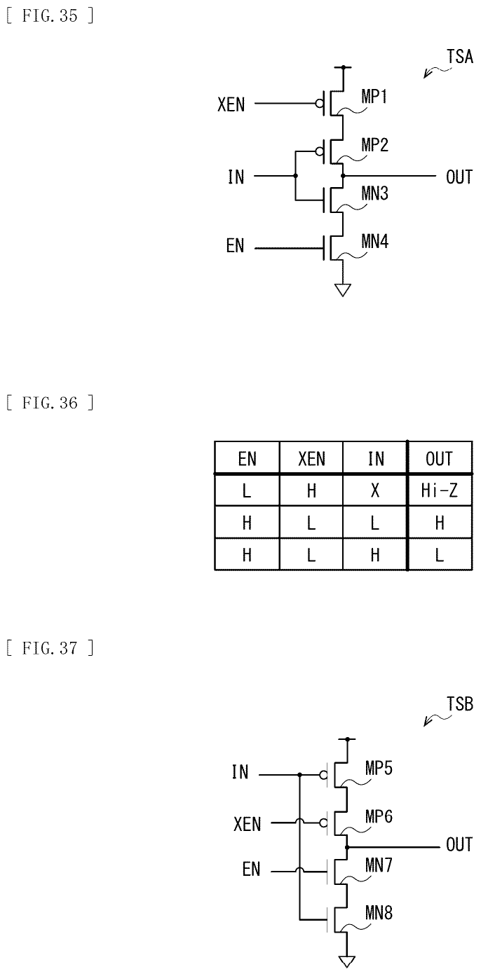

FIG. 35 illustrates a configuration example of the tristate inverter TS. This tristate inverter TS (a tristate inverter TSA) includes transistors MP1, MP2, MN3, and MN4. The transistors MP1 and MP2 are P-type MOS (Metal-Oxide Semiconductor) transistors, and the transistors MN3 and MN4 are N-type MOS transistors. The transistor MP1 has a gate to be supplied with a control signal XEN, a source coupled to the power supply node, and a drain coupled to a source of the transistor MP2. The transistor MP2 has a gate coupled to a gate of the transistor MN3, the source coupled to the drain of the transistor MP1, and a drain coupled to a drain of the transistor MN3. The transistor MN3 has the gate coupled to the gate of the transistor MP2, the drain coupled to the drain of the transistor MP2, and a source coupled to a drain of the transistor MN4. The transistor MN4 has a gate to be supplied with a control signal EN, the drain coupled to the source of the transistor MN3, and a source coupled to the ground node. An input signal IN is supplied to the gates of the transistors MP2 and MN3, and an output signal OUT is outputted from the drains of the transistors MP2 and MN3.

FIG. 36 illustrates a truth table of the tristate inverter TS. In FIG. 36, “X” indicates that either the high level or the low level is fine. In a case where the control signal EN is at the high level (H) and the control signal XEN is at the low level (L), the tristate inverter TS operates as an inverter. That is, the tristate inverter TS changes the output signal OUT to the high level in a case where the input signal IN is at the low level, and changes the output signal OUT to the low level in a case where the input signal IN is at the high level. In addition, in a case where the control signal EN is at the low level and the control signal XEN is at the high level, the tristate inverter TS changes the output impedance to the high impedance (Hi-Z).

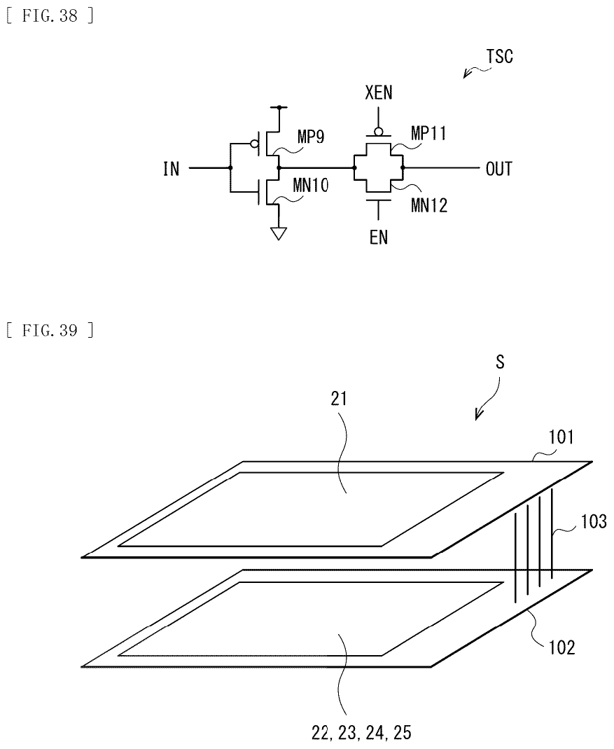

FIG. 37 illustrates another configuration example of the tristate inverter TS. This tristate inverter TS (a tristate inverter TSB) includes transistors MP5, MP6, MN7, and MN8. The transistors MP5 and MP6 are P-type MOS transistors, and the transistors MN7 and MN8 are N-type MOS transistors. The transistor MP5 has a gate coupled to a gate of the transistor MN8, a source coupled to the power supply node, and a drain coupled to a source of the transistor MP6. The transistor MP6 has a gate to be supplied with the control signal XEN, the source coupled to the drain of the transistor MP5, and a drain coupled to a drain of the transistor MN7. The transistor MN7 has a gate to be supplied with the control signal EN, the drain coupled to the drain of the transistor MP6, and a source coupled to a drain of the transistor MN8. The transistor MN8 has the gate coupled to the gate of the transistor MP5, the drain coupled to the source of the transistor MN7, and a source coupled to the ground node. The input signal IN is supplied to the gates of the transistors MP5 and MN8, and the output signal OUT is outputted from the drains of the transistors MP6 and MN7.

FIG. 38 illustrates another configuration example of the tristate inverter TS. This tristate inverter TS (a tristate inverter TSC) includes transistors MP9, MN10, MP11, and MN12. The transistors MP9 and MP11 are P-type MOS transistors, and the transistors MN10 and MN12 are N-type MOS transistors. The transistor MP9 has a gate coupled to a gate of the transistor MN10, a source coupled to the power supply node, and a drain coupled to a drain of the transistor MN10 and sources of the transistors MP11 and MN12. The transistor MN10 has the gate coupled to the gate of the transistor MP9, the drain coupled to the drain of the transistor MP9 and the sources of the transistors MP11 and MN12, and a source coupled to the ground node. The transistor MP11 has a gate to be supplied with the control signal XEN, the source coupled to the drains of the transistors MP9 and MN10 and the source of the transistor MN12, and a drain coupled to a drain of the transistor MN12. The transistor MN12 has a gate to be supplied with the control signal EN, the source coupled to the drains of the transistors MP9 and MN10 and the source of the transistor MP11, and the drain coupled to the drain of the transistor MP11. The input signal IN is supplied to the gates of the transistors MP9 and MN10, and the output signal OUT is outputted from the drains of the transistors MP11 and MN12.

### Modification Example 5

The photodetector 20 (FIG. 3) according to the embodiment described above may be formed on one semiconductor substrate, or may be formed on a plurality of semiconductor substrates. The present modification example is described in detail below with reference to some examples.

FIG. 39 illustrates an installation example of the photodetector 20. In this example, the photodetector 20 is formed on two semiconductor substrates 101 and 102. The semiconductor substrate 101 is disposed on side of the light-receiving surface S of the photodetector 20, and the semiconductor substrate 102 is disposed on side opposite to the light-receiving surface S of the photodetector 20. The semiconductor substrates 101 and 102 are superimposed on each other. A wiring of the semiconductor substrate 101 and a wiring of the semiconductor substrate 102 are coupled to each other by a wiring 103. It is possible to use, for example, metallic bonding such as Cu—Cu bonding or bump bonding for the wiring 103. The photodetector 20 is disposed over these two semiconductor substrates 101 and 102.

For example, the pixel array 21 is formed on the semiconductor substrate 101, and the detection signal generator 22, the TDC section 23, the histogram generator 24, and the distance calculator 25 are formed in a region corresponding to the pixel array 21 on the semiconductor substrate 102. It is to be noted that this is not limitative. At least a part of the detection signal generator 22, the TDC section 23, the histogram generator 24, and the distance calculator 25 may be formed in the region corresponding to the pixel array 21 on the semiconductor substrate 102.

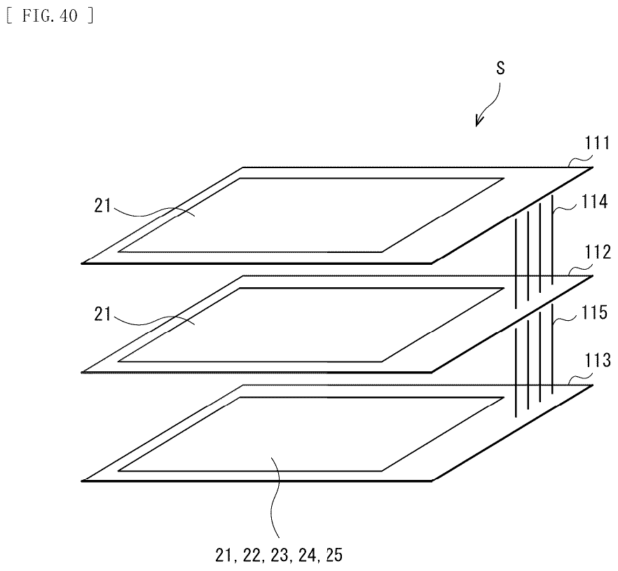

FIG. 40 illustrates another installation example of the photodetector 20. In this example, the photodetector 20 is formed on three semiconductor substrates 111, 112, and 113. The semiconductor substrate 111 is disposed on side of the light-receiving surface S of the photodetector 20. The semiconductor substrate 112 is disposed the second from side of the light-receiving surface S of the photodetector 20. The semiconductor substrate 113 is disposed on side opposite to the light-receiving surface S of the photodetector 20. The semiconductor substrates 111 and 112 are superimposed on each other, and the semiconductor substrates 112 and 113 are superimposed on each other. A wiring of the semiconductor substrate 111 and a wiring of the semiconductor substrate 112 are coupled to each other by a wiring 114. A wiring of the semiconductor substrate 112 and a wiring of the semiconductor substrate 113 are coupled to each other by a wiring 115. It is possible to use, for example, metallic bonding such as Cu—Cu bonding or bump bonding for the wirings 114 and 1153. The photodetector 20 is disposed over these three semiconductor substrates 111 to 113.

For example, a plurality of photodiodes PD of the pixel array 21 are formed on the semiconductor substrate 111, the current sources CS1 and the inverters IV1 of the pixel array 21 are formed in a region corresponding to the plurality of photodiodes PD on the semiconductor substrate 112, and remaining circuits of the pixel array 21, the detection signal generator 22, the TDC section 23, the histogram generator 24, and the distance calculator 25 are formed in a region corresponding to the plurality of photodiodes PD on the semiconductor substrate 113.

For example, in a case where the photodetector 20 is formed on one semiconductor substrate, for example, a plurality of OR circuit 31A and a plurality of OR circuits 31B in the detection signal generator 22 may be formed in a region where the pixel array 21 is formed. Further, a plurality of wave-shaping circuits 32A and a plurality of wave-shaping circuit 32B in the detection signal generator 22, the TDC section 23, the histogram generator 24, and the distance calculator 25 may be formed in a region different from the region where the pixel array 21 is formed. It is to be noted that this is not limitative. The detection signal generator 22, the TDC section 23, the histogram generator 24, and the distance calculator 25 may be formed in a region different from the region where the pixel array 21 is formed.

### Other Modification Examples

Two or more of these modification examples may be combined.

### 2. Application Example to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

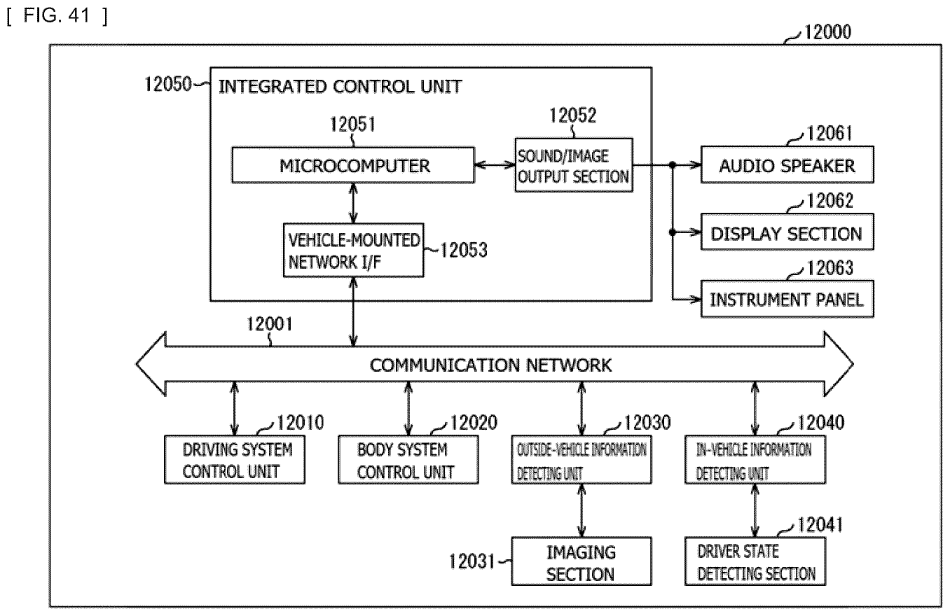

FIG. 41 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 41, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 41, an audio speaker 12061, a display section 12062, and an instrument panel 12063 are illustrated as the output device. The display section 12062 may, for example, include at least one of an on-board display and a head-up display.

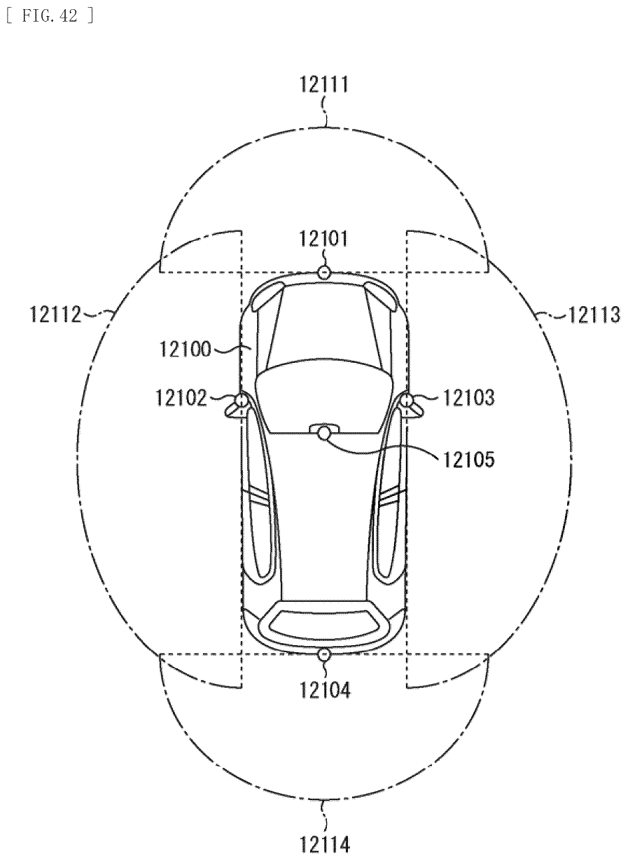

FIG. 42 is a diagram depicting an example of the installation position of the imaging section 12031.

In FIG. 42, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 42 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure may be applied to the imaging section 12031 among the components described above. Accordingly, in the vehicle control system 12000, it is possible to enhance detection accuracy of time (a TOF value) and a distance. As a result, this allows the vehicle control system 12000 to implement, with high accuracy, collision avoidance or shock mitigation for vehicles, a following driving function based on vehicle-to-vehicle distance, a vehicle speed maintaining driving function, a warning function of collision of the vehicle, a warning function of deviation of the vehicle from a lane, and the like.

Although the present technology has been described above with reference to some embodiments, some modification examples, and specific application examples thereof, the present technology is not limited to these embodiments and the like, and may be modified in a variety of ways.

For example, in each embodiment described above, the light-receiving pixel P as illustrated in FIGS. 4 and 6 is provided; however, the circuit configuration of the light-receiving pixel P is not limited thereto, and any of various circuit configurations is applicable to the light-receiving pixel P.

It is to be noted that the effects described herein are merely illustrative and non-limiting, and may further include other effects.

It is to be noted that the present technology may have the following configurations. According to the present technology having the following configurations, it is possible to enhance detection accuracy.
(1)

A photodetection device including:
a plurality of light-receiving pixels that is each configured to detect a light pulse and generate a pulse signal including a pulse corresponding to the light pulse, and includes a plurality of first light-receiving pixels and a plurality of second light-receiving pixels, the plurality of first light-receiving pixels provided at positions not adjacent to each other, and the plurality of second light-receiving pixels provided at positions not adjacent to each other;
a first OR circuit that is configured to generate a first detection signal by performing an OR operation of a plurality of the pulse signals generated by the plurality of first light-receiving pixels;
a first timing code generation circuit that is configured to generate a first timing code corresponding to a timing when the pulse included in the first detection signal occurs;
a second OR circuit that is configured to generate a second detection signal by performing an OR operation of a plurality of the pulse signals generated by the plurality of second light-receiving pixels;
a second timing code generation circuit that is configured to generate a second timing code corresponding to a timing when the pulse included in the second detection signal occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.
(2)

The photodetection device according to (1), in which
the first timing code generation circuit is configured to generate the first timing code corresponding to the timing when the pulse included in the first detection signal occurs, and configured to output the first timing code at a timing when a pulse after the pulse included in the first detection signal occurs, and
the second timing code generation circuit is configured to generate the second timing code corresponding to the timing when the pulse included in the second detection signal occurs, and configured to output the second timing code at a timing when a pulse after the pulse in the second detection signal occurs.
(3)

The photodetection device according to (1) or (2), in which the first histogram generation circuit is configured to generate the first composite signal by synthesizing the plurality of bit signals in the first signal and the plurality of bit signals in the second signal in bit units.
(4)

The photodetection device according to (3), in which the first histogram generation circuit is configured to perform an OR operation of a first bit signal in the first signal and a second bit signal corresponding to the first bit signal in the second signal, thereby synthesizing the first bit signal and the second bit signal.
(5)

The photodetection device according to (3), in which the first histogram generation circuit is configured to perform an OR operation and an AND operation of a first bit signal in the first signal and a second bit signal corresponding to the first bit signal in the second signal and perform an exclusive OR operation of a result of the OR operation and a result of the AND operation, thereby synthesizing the first bit signal and the second bit signal.
(6)

The photodetection device according to (3), in which the first histogram generation circuit is configured to delay one of a first bit signal in the first signal and a second bit signal corresponding to the first bit signal in the second signal and perform an OR operation of a delayed signal and an undelayed signal, the delayed signal being the one of the first bit signal and the second bit signal, the undelayed signal being the other of the first bit signal and the second bit signal, thereby synthesizing the first bit signal and the second bit signal.
(7)

The photodetection device according to any one of (1) to (6), in which
the plurality of light-receiving pixels is provided side by side in a first direction and a second direction intersecting with the first direction,
each of the plurality of first light-receiving pixels is adjacent to at least one of the plurality of second light-receiving pixels in the first direction, and is adjacent to at least one of the plurality of second light-receiving pixels in the second direction, and
each of the plurality of second light-receiving pixels is adjacent to at least one of the plurality of first light-receiving pixels in the first direction, and is adjacent to at least one of the plurality of first light-receiving pixels in the second direction.
(8)

The photodetection device according to any one of (1) to (7), further including:
a third OR circuit;
a third timing code generation circuit;
a fourth OR circuit;
a fourth timing code generation circuit; and
a second histogram generation circuit, in which
the plurality of light-receiving pixels further includes a plurality of third light-receiving pixels and a plurality of fourth light-receiving pixels, the plurality of third light-receiving pixels provided at positions not adjacent to each other, and the plurality of fourth light-receiving pixels provided at positions not adjacent to each other,
the plurality of first light-receiving pixels and the plurality of second light-receiving pixels are provided side by side in a first pixel region,
the plurality of third light-receiving pixels and the plurality of fourth light-receiving pixels are provided side by side in a second pixel region adjacent to the first pixel region,
the third OR circuit is configured to generate a third detection signal by performing an OR operation of a plurality of the pulse signals generated by the plurality of third light-receiving pixels,
the third timing code generation circuit is configured to generate a third timing code corresponding to a timing when the pulse included in the third detection signal occurs,
the fourth OR circuit is configured to generate a fourth detection signal by performing an OR operation of a plurality of the pulse signals generated by the plurality of fourth light-receiving pixels,
the fourth timing code generation circuit is configured to generate a fourth timing code corresponding to a timing when the pulse included in the fourth detection signal occurs, and
the second histogram generation circuit is configured to generate a third signal including a plurality of bit signals by decoding the third timing code and generate a fourth signal including a plurality of bit signals by decoding the fourth timing code, configured to generate a second composite signal by synthesizing the third signal and the fourth signal, and configured to generate a second histogram on the basis of the second composite signal.
(9)

The photodetection device according to (8), in which
one of the plurality of first light-receiving pixels and one of the plurality of third light-receiving pixels are adjacent to each other with a boundary between the first pixel region and the second pixel region interposed therebetween, and
one of the plurality of second light-receiving pixels and one of the plurality of fourth light-receiving pixels are adjacent to each other with the boundary between the first pixel region and the second pixel region interposed therebetween.
(10)

The photodetection device according to (8), in which
one of the plurality of first light-receiving pixels and one of the plurality of fourth light-receiving pixels are adjacent to each other with a boundary between the first pixel region and the second pixel region interposed therebetween, and
one of the plurality of second light-receiving pixels and one of the plurality of third light-receiving pixels are adjacent to each other with the boundary between the first pixel region and the second pixel region interposed therebetween.
(11)

The photodetection device according to any one of (1) to (7), further including a controller that is configured to set a pixel region where a light reception operation is activated among the plurality of light-receiving pixels, in which
the first OR circuit performs an OR operation of a plurality of the pulse signals generated by a plurality of light-receiving pixels belonging to the pixel region among the plurality of first light-receiving pixels, and
the second OR circuit performs an OR operation of a plurality of the pulse signals generated by a plurality of light-receiving pixels belonging to the pixel region among the plurality of second light-receiving pixels.
(12)

The photodetection device according to any one of (1) to (12), in which
the light pulse includes a spot light beam, and
a radius of the spot light beam is substantially equal to a size of each of the plurality of light-receiving pixels.
(13)

The photodetection device according to any one of (1) to (13), in which
the plurality of light-receiving pixels is provided side by side in a first region on a semiconductor substrate, and
the first OR circuit and the second OR circuit are provided in the first region on the semiconductor substrate.
(14)

The photodetection device according to any one of (1) to (13), in which
the plurality of light-receiving pixels is provided side by side in a second region on a first semiconductor substrate, and
at least a part of the first timing code generation circuit, the second timing code generation circuit, and the first histogram generation circuit is provided in the second region on a second semiconductor substrate that is superimposed on the first semiconductor substrate.
(15)

The photodetection device according to any one of (1) to (13), in which
each of the plurality of light-receiving pixels includes a light-receiving element and a light reception circuit,
a plurality of the light-receiving elements in the plurality of light-receiving pixels is provided side by side in a third region on a first semiconductor substrate,
a part of circuits other than the plurality of light-receiving elements in the plurality of light-receiving pixels is provided in the third region on a second semiconductor substrate that is superimposed on the first semiconductor substrate, and
at least a part of remaining circuits in the plurality of light-receiving pixels, the first timing code generation circuit, the second timing code generation circuit, and the first histogram generation circuit is provided in the third region on a third semiconductor substrate that is superimposed on the second semiconductor substrate.
(16)

A photodetection device including:
a plurality of light-receiving pixels that is each configured to detect a light pulse and generate a pulse signal including a pulse corresponding to the light pulse, and includes a plurality of first light-receiving pixels and a plurality of second light-receiving pixels;
a first timing code generation circuit that is configured to generate a first timing code corresponding to a timing when the pulse included in the pulse signal generated by the first light-receiving pixel occurs;
a second timing code generation circuit that is configured to generate a second timing code corresponding to a timing when the pulse included in the pulse signal generated by the second light-receiving pixel occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.
(17)

The photodetection device according to (16), in which
the first timing code generation circuit is configured to generate the first timing code corresponding to the timing when the pulse included in the pulse signal generated by the first light-receiving pixel occurs, and configured to output the first timing code at a timing when a pulse after the pulse in the pulse signal generated by the first light-receiving pixel occurs, and
the second timing code generation circuit is configured to generate the second timing code corresponding to the timing when the pulse included in the pulse signal generated by the second light-receiving pixel occurs, and configured to output the second timing code at a timing when a pulse after the pulse in the pulse signal generated by the second light-receiving pixel occurs.
(18)

A photodetection system including:
a light source that is configured to emit a first light pulse;
a plurality of light-receiving pixels that is each configured to detect a second light pulse corresponding to the first light pulse and generate a pulse signal including a pulse corresponding to the second light pulse, and includes a plurality of first light-receiving pixels and a plurality of second light-receiving pixels, the plurality of first light-receiving pixels provided at positions not adjacent to each other, and the plurality of second light-receiving pixels provided at positions not adjacent to each other;
a first OR circuit that is configured to generate a first detection signal by performing an OR operation of a plurality of the pulse signals generated by the plurality of first light-receiving pixels:
a first timing code generation circuit that is configured to generate a first timing code corresponding to a timing when the pulse included in the first detection signal occurs;
a second OR circuit that is configured to generate a second detection signal by performing an OR operation of a plurality of the pulse signals generated by the plurality of second light-receiving pixels;
a second timing code generation circuit that is configured to generate a second timing code corresponding to a timing when the pulse included in the second detection signal occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on the basis of the first composite signal.

The present application claims the benefit of Japanese Priority Patent Application JP2022-126612 filed with the Japan Patent Office on Aug. 8, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetection device comprising:
a plurality of light-receiving pixels that is each configured to detect a light pulse and generate a pulse signal including a pulse corresponding to the light pulse, and includes a plurality of first light-receiving pixels and a plurality of second light-receiving pixels, the plurality of first light-receiving pixels provided at positions not adjacent to each other, and the plurality of second light-receiving pixels provided at positions not adjacent to each other;
a first OR circuit that is configured to generate a first detection signal by performing an OR operation of a plurality of the pulse signals generated by the plurality of first light-receiving pixels;
a first timing code generation circuit that is configured to generate a first timing code corresponding to a timing when the pulse included in the first detection signal occurs;
a second OR circuit that is configured to generate a second detection signal by performing an OR operation of a plurality of the pulse signals generated by the plurality of second light-receiving pixels;
a second timing code generation circuit that is configured to generate a second timing code corresponding to a timing when the pulse included in the second detection signal occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on a basis of the first composite signal.

2. The photodetection device according to claim 1, wherein
the first timing code generation circuit is configured to generate the first timing code corresponding to the timing when the pulse included in the first detection signal occurs, and configured to output the first timing code at a timing when a pulse after the pulse included in the first detection signal occurs, and
the second timing code generation circuit is configured to generate the second timing code corresponding to the timing when the pulse included in the second detection signal occurs, and configured to output the second timing code at a timing when a pulse after the pulse in the second detection signal occurs.

3. The photodetection device according to claim 1, wherein the first histogram generation circuit is configured to generate the first composite signal by synthesizing the plurality of bit signals in the first signal and the plurality of bit signals in the second signal in bit units.

4. The photodetection device according to claim 3, wherein the first histogram generation circuit is configured to perform an OR operation of a first bit signal in the first signal and a second bit signal corresponding to the first bit signal in the second signal, thereby synthesizing the first bit signal and the second bit signal.

5. The photodetection device according to claim 3, wherein the first histogram generation circuit is configured to perform an OR operation and an AND operation of a first bit signal in the first signal and a second bit signal corresponding to the first bit signal in the second signal and perform an exclusive OR operation of a result of the OR operation and a result of the AND operation, thereby synthesizing the first bit signal and the second bit signal.

6. The photodetection device according to claim 3, wherein the first histogram generation circuit is configured to delay one of a first bit signal in the first signal and a second bit signal corresponding to the first bit signal in the second signal and perform an OR operation of a delayed signal and an undelayed signal, the delayed signal being the one of the first bit signal and the second bit signal, the undelayed signal being the other of the first bit signal and the second bit signal, thereby synthesizing the first bit signal and the second bit signal.

7. The photodetection device according to claim 1, wherein
the plurality of light-receiving pixels is provided side by side in a first direction and a second direction intersecting with the first direction,
each of the plurality of first light-receiving pixels is adjacent to at least one of the plurality of second light-receiving pixels in the first direction, and is adjacent to at least one of the plurality of second light-receiving pixels in the second direction, and
each of the plurality of second light-receiving pixels is adjacent to at least one of the plurality of first light-receiving pixels in the first direction, and is adjacent to at least one of the plurality of first light-receiving pixels in the second direction.

8. The photodetection device according to claim 1, further comprising:
a third OR circuit;
a third timing code generation circuit;
a fourth OR circuit;
a fourth timing code generation circuit; and
a second histogram generation circuit, wherein
the plurality of light-receiving pixels further includes a plurality of third light-receiving pixels and a plurality of fourth light-receiving pixels, the plurality of third light-receiving pixels provided at positions not adjacent to each other, and the plurality of fourth light-receiving pixels provided at positions not adjacent to each other,
the plurality of first light-receiving pixels and the plurality of second light-receiving pixels are provided side by side in a first pixel region,
the plurality of third light-receiving pixels and the plurality of fourth light-receiving pixels are provided side by side in a second pixel region adjacent to the first pixel region,
the third OR circuit is configured to generate a third detection signal by performing an OR operation of a plurality of the pulse signals generated by the plurality of third light-receiving pixels,
the third timing code generation circuit is configured to generate a third timing code corresponding to a timing when the pulse included in the third detection signal occurs,
the fourth OR circuit is configured to generate a fourth detection signal by performing an OR operation of a plurality of the pulse signals generated by the plurality of fourth light-receiving pixels,
the fourth timing code generation circuit is configured to generate a fourth timing code corresponding to a timing when the pulse included in the fourth detection signal occurs, and
the second histogram generation circuit is configured to generate a third signal including a plurality of bit signals by decoding the third timing code and generate a fourth signal including a plurality of bit signals by decoding the fourth timing code, configured to generate a second composite signal by synthesizing the third signal and the fourth signal, and configured to generate a second histogram on a basis of the second composite signal.

9. The photodetection device according to claim 8, wherein
one of the plurality of first light-receiving pixels and one of the plurality of third light-receiving pixels are adjacent to each other with a boundary between the first pixel region and the second pixel region interposed therebetween, and
one of the plurality of second light-receiving pixels and one of the plurality of fourth light-receiving pixels are adjacent to each other with the boundary between the first pixel region and the second pixel region interposed therebetween.

10. The photodetection device according to claim 8, wherein
one of the plurality of first light-receiving pixels and one of the plurality of fourth light-receiving pixels are adjacent to each other with a boundary between the first pixel region and the second pixel region interposed therebetween, and
one of the plurality of second light-receiving pixels and one of the plurality of third light-receiving pixels are adjacent to each other with the boundary between the first pixel region and the second pixel region interposed therebetween.

11. The photodetection device according to claim 1, further comprising a controller that is configured to set a pixel region where a light reception operation is activated among the plurality of light-receiving pixels, wherein
the first OR circuit performs an OR operation of a plurality of the pulse signals generated by a plurality of light-receiving pixels belonging to the pixel region among the plurality of first light-receiving pixels, and
the second OR circuit performs an OR operation of a plurality of the pulse signals generated by a plurality of light-receiving pixels belonging to the pixel region among the plurality of second light-receiving pixels.

12. The photodetection device according to claim 1, wherein
the light pulse comprises a spot light beam, and
a radius of the spot light beam is substantially equal to a size of each of the plurality of light-receiving pixels.

13. The photodetection device according to claim 1, wherein
the plurality of light-receiving pixels is provided side by side in a first region on a semiconductor substrate, and
the first OR circuit and the second OR circuit are provided in the first region on the semiconductor substrate.

14. The photodetection device according to claim 1, wherein
the plurality of light-receiving pixels is provided side by side in a second region on a first semiconductor substrate, and
at least a part of the first timing code generation circuit, the second timing code generation circuit, and the first histogram generation circuit is provided in the second region on a second semiconductor substrate that is superimposed on the first semiconductor substrate.

15. The photodetection device according to claim 1, wherein
each of the plurality of light-receiving pixels includes a light-receiving element and a light reception circuit,
a plurality of the light-receiving elements in the plurality of light-receiving pixels is provided side by side in a third region on a first semiconductor substrate,
a part of circuits other than the plurality of light-receiving elements in the plurality of light-receiving pixels is provided in the third region on a second semiconductor substrate that is superimposed on the first semiconductor substrate, and
at least a part of remaining circuits in the plurality of light-receiving pixels, the first timing code generation circuit, the second timing code generation circuit, and the first histogram generation circuit is provided in the third region on a third semiconductor substrate that is superimposed on the second semiconductor substrate.

16. A photodetection device comprising:
a plurality of light-receiving pixels that is each configured to detect a light pulse and generate a pulse signal including a pulse corresponding to the light pulse, and includes a plurality of first light-receiving pixels and a plurality of second light-receiving pixels;
a first timing code generation circuit that is configured to generate a first timing code corresponding to a timing when the pulse included in the pulse signal generated by the first light-receiving pixel occurs;
a second timing code generation circuit that is configured to generate a second timing code corresponding to a timing when the pulse included in the pulse signal generated by the second light-receiving pixel occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on a basis of the first composite signal.

17. The photodetection device according to claim 16, wherein
the first timing code generation circuit is configured to generate the first timing code corresponding to the timing when the pulse included in the pulse signal generated by the first light-receiving pixel occurs, and configured to output the first timing code at a timing when a pulse after the pulse in the pulse signal generated by the first light-receiving pixel occurs, and
the second timing code generation circuit is configured to generate the second timing code corresponding to the timing when the pulse included in the pulse signal generated by the second light-receiving pixel occurs, and configured to output the second timing code at a timing when a pulse after the pulse in the pulse signal generated by the second light-receiving pixel occurs.

18. A photodetection system comprising:
a light source that is configured to emit a first light pulse;
a plurality of light-receiving pixels that is each configured to detect a second light pulse corresponding to the first light pulse and generate a pulse signal including a pulse corresponding to the second light pulse, and includes a plurality of first light-receiving pixels and a plurality of second light-receiving pixels, the plurality of first light-receiving pixels provided at positions not adjacent to each other, and the plurality of second light-receiving pixels provided at positions not adjacent to each other;
a first OR circuit that is configured to generate a first detection signal by performing an OR operation of a plurality of the pulse signals generated by the plurality of first light-receiving pixels:
a first timing code generation circuit that is configured to generate a first timing code corresponding to a timing when the pulse included in the first detection signal occurs;
a second OR circuit that is configured to generate a second detection signal by performing an OR operation of a plurality of the pulse signals generated by the plurality of second light-receiving pixels;
a second timing code generation circuit that is configured to generate a second timing code corresponding to a timing when the pulse included in the second detection signal occurs; and
a first histogram generation circuit that is configured to generate a first signal including a plurality of bit signals by decoding the first timing code and generate a second signal including a plurality of bit signals by decoding the second timing code, configured to generate a first composite signal by synthesizing the first signal and the second signal, and configured to generate a first histogram on a basis of the first composite signal.
